(19) United States
(12) Patent Application Publication
(10) Pub. No.: US 2007/0235742 A1
(43) Pub. Date: Oct. 11, 2007

(54) Light emitting device

(75) Inventors: Manabu Tobise, Kanagawa (JP); Masaru Kinoshita, Kanagawa (JP)

Correspondence Address: BIRCH STEWART KOLASCH & BIRCH, PO BOX 747, FALLS CHURCH, VA, 22040-0747, US

(73) Assignee: FUJIFILM Corporation

(21) Appl. No.: 11/725,523

(22) Filed: Mar. 20, 2007

(30) Foreign Application Priority Data
Mar. 23, 2006 (JP) 2006-081472
Sep. 28, 2006 (JP) 2006-264842

(51) Int. Cl. H01L 27/15

(52) U.S. Cl. 257/79

(57) ABSTRACT

A light emitting device is provided which has at least a light emitting layer between a pair of electrodes, wherein the light emitting layer is divided into plural layers in the thickness direction thereof, and an intermediate layer containing at least one of a charge transport material or a light emitting material is positioned between each of the divided layers of the light emitting layer. A light emitting device having a high external quantum efficiency is provided.

### CROSS-REFERENCE TO RELATED APPLICATION

This application claims priority under 35 USC 119 from Japanese Patent Application Nos. 2006-081472 and 2006-264842, the disclosures of which are incorporated by reference herein.

### BACKGROUND OF THE INVENTION

1. Field of the Invention

The present invention relates to a light emitting device which has improved external quantum efficiency, and in particular, to a light emitting device which can be effectively applied to a surface light source for a full color display, a backlight, an illumination light source or the like; or a light source array for a printer or the like.

2. Description of the Related Art

A light emitting device is composed of a light emitting layer or a plurality of functional layers containing a light emitting layer, and a pair of electrodes sandwiching these layers. The light emitting device is a device for obtaining luminescence by utilizing at least either one of luminescence from excitons each of which is obtained by recombining an electron injected from a cathode with a hole injected from an anode to produce the exciton, or luminescence from excitons of other molecules produced by energy transmission from the above-described excitons.

Heretofore, a light emitting device has been developed by using a laminate structure from integrated layers in which each layer is functionally differentiated, whereby brightness and device efficiency are remarkably improved. For example, it is described in “Science”, vol. 267, No. 3, page 1332, (1995) that a two-layer laminated type device obtained by laminating a hole transport layer and a light emitting layer also functioning as an electron transport layer; a three-layer laminated type device obtained by laminating a hole transport layer, a light emitting layer, and an electron transport layer; and a four-layer laminated type device obtained by laminating a hole transport layer, a light emitting layer, a hole blocking layer, and an electron transport layer have been frequently used.

However, many problems still remain for putting light emitting devices to practical use. First, there is a need to attain a high external quantum efficiency, and second, there is a need to attain a high driving durability. Particularly, deterioration of quality during continuous driving is one of most prominent subjects.

For example, there has been disclosed in JP-A No. 2003-123984 an attempt to dispose an interface layer of 0.1 nm to 5 nm as a barrier layer between a light emitting layer and a hole transport layer and retard the migration of holes, to thereby control the migration balance between holes and electrons and enhance the external quantum efficiency. However, this means potentially involves a problem of lowering the brightness and increasing the driving voltage since the migration of all of the carriers is lowered, as well as a problem of lowering the driving durability, since the time that the carriers stay in the device is made longer.

Further, a configuration in which a light emitting unit containing a light emitting layer and a functional layer is stacked in a multi-layer structure referred to as a multi-photon is known. For example, JP-A No. 6-310275 discloses a configuration in which plural light emitting units including an organic electroluminescence device (hereinafter, referred to as an “organic EL device” in some cases) are isolated by an insulation layer, and opposing electrodes are provided for each of the light emitting units. However, in this configuration, since the insulation layer and the electrode between the light emitting units hinder the taking out of light emission, light emitted from each of the light emitting units cannot substantially be utilized sufficiently. Further, this is not a means for improving the low external quantum efficiency inherent to each of the light emitting units. JP-A No. 8-162273 similarly discloses a configuration in which light emitting units are stacked and each of the light light emitting units is isolated with an insulation layer.

JP-A No. 2003-45676 discloses a multi-photon type organic EL device, in which a plurality of light emitting layers are isolated from each other by an electrically insulative charge generation layer. However, in this configuration as well, the light emitting units are merely stacked in a plurality, and this cannot provide a means for improving the low external quantum efficiency inherent to each of the light emitting units.

Compatibility between high external quantum efficiency and high driving durability is extremely important for designing a light emitting device which is practically useful, and this is a subject for which improvement is continuously demanded.

### SUMMARY OF THE INVENTION

The present invention has been made in view of the above circumstances and provides a light emitting device having at least a light emitting layer between a pair of electrodes, wherein the light emitting layer is divided into plural layers in the thickness direction thereof, and an intermediate layer containing at least one of a charge transport material or a light emitting material is positioned between each of the divided layers of the light emitting layer.

### BRIEF DESCRIPTION OF THE DRAWINGS

FIG. 1 is a conceptual view of the layer configuration of a comparative light emitting device, in which an anode 1, a hole injection layer 2, a hole transport layer 3, a light emitting layer 4, an electron transporting layer 5, an electron injecting layer 6, and a cathode 7 are stacked.

FIG. 2 is a conceptual view of an example of a light emitting device according to the invention in which a light emitting layer is bisected with an intermediate layer being disposed therebetween, and having divided light emitting layers 4a and 4b and an intermediate layer 8.

FIG. 3 is a conceptual view of a layer configuration of another example of the light emitting device according to the present invention in which a light emitting layer is divided into four layers with an intermediate layer being disposed between each of the four layers, and which has divided light emitting layers 4a, 4b, 4c and 4d and divided intermediate layers 8a, 8b and 8c.

FIG. 4 is a conceptual view of a layer configuration of another example of the light emitting device according to the present invention in which a light emitting layer is divided into three layers with an intermediate layer being disposed between each of the divided layers, and an electron blocking layer between an anode and the light emitting layer and a hole blocking layer between a cathode and the light emitting layer are provided.

### DETAILED DESCRIPTION OF THE INVENTION

The invention is intended to provide a light emitting device that is improved in external quantum efficiency.

The light emitting device of the invention is a light emitting device having at least a light emitting layer between a pair of electrodes in which the light emitting device is divided into plural layers along the thickness direction thereof and an intermediate layer is positioned between each of the divided layers of the light emitting layer.

The intermediate layer is, preferably, a conductive charge blocking layer.

That is, the light emitting device of the invention comprises a multiple stacked layer constitution having a light emitting layer finely divided into thin layers along the thickness direction thereof and an intermediate layer interposed between each of the finely divided light emitting layers of the light emitting layer.

More preferably, the light emitting device of the present invention has a multi-layer configuration comprising a light emitting layer which is divided into plural thin layers in thickness direction thereof, and an intermediate layer being disposed between each of the thin layers, an electron blocking layer between an anode and the light emitting layer, and a hole blocking layer between a cathode and the light emitting layer.

As a result of analysis of the cause for the low external quantum efficiency in light emitting devices, it has been estimated by the present inventors that main light emission occurs near an extremely limited interface between the light emitting layer and an adjacent layer, and that charges are localized to the extremely limited interface to gradually cause degradation until re-combination occurs.

As a result of an earnest search for a means of improvement, the present inventors have achieved the invention based on the finding that the problem can be solved by finely dividing the light emitting layer into plural thin light emitting layers along the thickness direction thereof and disposing a conductive charge blocking layer as an intermediate layer between each of the finely divided light emitting layers. That is, the distance between regions where electrons and holes are localized is shortened to increase the re-combination speed and improve the efficiency. Further, the light emitting units of each of the thin layers are joined by the conductive charge blocking layer, and thus, the light generated in each of the devices can be taken out efficiently to the outside without greatly increasing the driving resistance. Accordingly, light emission at high brightness can be obtained. Further, by incorporation of a light emitting material in the conductive charge blocking layer, this layer can also emit light, and it is possible to obtain light emission with even higher brightness.

The invention provides a light emitting device outstandingly improved in external quantum efficiency. Further, it provides a light emitting device that is improved in external quantum efficiency, as well as in driving durability.

While the light emitting device of the invention may be either an organic EL device or an inorganic EL device, even greater effect can be obtained particularly with the organic EL device.

### 1. Constitution of Device

The device of the invention is a light emitting device having at least a light emitting layer interposed between a pair of electrodes in which the light emitting layer is divided along the thickness direction thereof and an intermediate layer containing at least one of a charge transport material or a light emitting material is contained between each of the divided light emitting layers of the light emitting layer. The intermediate layer functions as a conductive charge blocking layer. In the present application, the finely divided light emitting layers, into which the light emitting layer is divided in the thickness direction thereof, are sometimes referred to as “unit light emitting layers”.

The thickness of the unit light emitting layer in the invention is preferably 2 nm or more and 50 nm or less, more preferably 2 nm or more and 20 nm or less, and further preferably 2 nm or more and 10 nm or less.

The light emitting layer in the invention is finely divided along the thickness direction thereof preferably into 3 layers or more and 30 layers or less, and more preferably into 4 layers or more and 15 layers or less.

The unit light emitting layers in the invention are connected by an intermediate layer containing at least one of the charge transport material or the light emitting material. Preferably, the device comprises at least four unit light emitting layers and three intermediate layers connecting them along the thickness direction thereof.

One embodiment of the present invention preferably comprises an electron blocking layer between an anode and an unit light emitting layer nearest to the anode and adjacent to the unit light emitting layer. Another embodiment of the present invention preferably comprises a hole blocking layer between an cathode and an unit light emitting layer nearest to the cathode and adjacent to the unit light emitting layer.

The most preferable embodiment of the present invention comprises an electron blocking layer between an anode and an unit light emitting layer nearest to the anode and adjacent to the unit light emitting layer nearest to the anode, and a hole blocking layer between an cathode and an unit light emitting layer nearest to the cathode and adjacent to the unit light emitting layer nearest to the cathode.

The intermediate layer in the invention preferably contains at least one of the charge transport material or the light emitting material. Preferably, a hole transport material and an electron transport material are contained as the charge transporting material.

Preferably, the intermediate layer contains a phosphorescence material as the light emitting material.

### (Intermediate Layer)

The intermediate layer in the invention will be described in more detail.

The intermediate layer in the invention functions as a conductive charge blocking layer.

The conductive charge blocking layer in the invention is a layer having a function of suppressing electrons transported from a cathode to a light emitting layer from passing through to an anode, and suppressing holes transported from an anode to the light emitting layer from passing through to the cathode, but this is not a layer for completely inhibiting the migration of carriers.

### 1) Conductive Charge Blocking Material

The conductive charge blocking material contained in the intermediate layer of the invention is not particularly limited so long as it is an electron transport material capable of accepting electrons from a layer adjacent to the intermediate layer at the cathode side thereof and transferring the electrons to a layer adjacent to the intermediate layer at the anode side thereof, or a hole transporting material capable of accepting holes from the layer adjacent to the intermediate layer at the anode side thereof and transferring the holes to the a layer adjacent to the intermediate layer at the cathode side thereof, while blocking the migration of the carriers to a certain degree.

In particular, examples of the conductive charge blocking material which is contained in the intermediate layer in the present invention include a triazole derivative; an oxazole derivative; an oxadiazole derivative; a fluorenone derivative; an anthraquinodimethane derivative; an anthrone derivative; a diphenylquinone derivative; a thiopyran dioxide derivative; a carbodiimide derivative; a fluorenylidenemethane derivative; a distyrylpyrazine derivative; heterocyclic tetracarboxylic anhydrides such as naphthalene perylene; a phthalocyanine derivative; various kinds of metal complexes typical in metal complexes of an 8-quinolinol derivative, metal phthalocyanine, and metal complexes with benzoxazole or benzothiazole as a ligand; electrically conductive polymer oligomers such as an aniline-based copolymer, a thiophene oligomer and polythiophene; and polymer compounds such as a polythiophene derivative, a polyphenylene derivative, a polyphenylenevinylene derivative and a polyfluorene derivative.

### 2) Constitution of Intermediate Layer

The intermediate layer in the invention can be disposed as an organic compound layer in which the material described above is co-vapor deposited together with the charge transport material (host) and/or the light emitting material in the light emitting layer.

In general, the constituent ratio of the intermediate layer preferably comprises from 5 mass % to 90 mass % of the conductive charge blocking material, from 0 mass % to 30 mass % of the light emitting material, and from 0 mass % to 95 mass % of the charge transport material (total for the light emitting material and the charge transport material: 10 mass % to 95 mass %), further preferably, from 10 mass % to 80 mass % of the conductive charge blocking material, 0 mass % to 30 mass % of the light emitting material, and 0 mass % to 90 mass % of the charge transporting material (total for the light emitting material and the charge transporting material: 20 mass % to 80 mass %), and even further preferably, from 30 mass % to 70 mass % the conductive charge blocking material, from 0 mass % to 30 mass % of the light emitting material, and from 0 mass % to 70 mass % of the charge transport material (total for the light emitting material and the charge transport material: 30 mass % to 70 mass %).

In a case where the conductive charge blocking material exceeds 90 mass %, migration of carriers is hindered greatly to increase the driving voltage, which is not preferred. In a case where the conductive charge blocking material is less than 5 mass %, since the charge blocking performance is scarcely exhibited, this results in a problem in that the effect of improving the external quantum efficiency is not obtained, which is not preferred.

### 3) Thickness

For lowering the driving voltage, in general, the thickness of the intermediate layer in the invention is preferably from 3 nm to 100 nm, more preferably from 5 nm to 30 nm ,and even more preferably from 10 nm to 20 nm.

In a case where the thickness exceeds 100 nm, migration of carriers is hindered greatly to result in a problem of increasing the driving voltage, which is not preferred. In a case where the thickness is less than 3 nm, the layer is not formed sufficiently and partially or entirely loses the function as the conductive charge blocking layer, which is not preferred.

### 4) Number of Layers

The number of layers of the intermediate layer in the invention is preferably from 1 to 49, more preferably from 2 to 29, and further preferably from 3 to 14.

### (Light Emitting Layer)

The light emitting layer used in the light emitting device of the invention is an organic EL light emitting layer or an inorganic EL light emitting layer. For each of the light emitting layers to be explained specifically in the description for respective light emitting devices.

In the constitution of the invention, the light emitting layer is finely divided into thin layers in the direction of the thickness and, finally divided, preferably, into 3 layers or more, 30 layers or less, more preferably, 4 layers or more and 15 layers or less.

For the light emitting layer in the invention, the thickness of the unit light emitting layer finely divided in the direction of the thickness is extremely thin as 2 nm or 50 nm or less, more preferably, 2 nm or and 20 nm or less and further preferably, 2 nm or more and 10 nm or less.

When a current is supplied to the light emitting device in the invention, holes and electrons are generated and accumulated near the interface between the unit of the light emitting layer and the adjacent conductive charge blocking layer and they are re-combined to emit light. In the invention, since the light emitting layer is finely divided into plural units and the thickness of each unit is thin, a region where the hole accumulate and a region where electrons accumulate in each of the units is closer, so that they are re-combined efficiently. Further, since the staying time of the holes and the electrons is also shortened, and consumption by reaction not contributing to light emission is decreased, the efficiency is further improved.

A plurality of light emitting layers in the invention may be layers showing light emission identical with each other or showing light emission different from each other. For example, in a case of a layer showing identical light emission, light emission at high brightness can be taken out. On the other hand, in a case of light emission at a wavelength different from each other, it is possible to obtain light emission at a desired tone, or obtain white light emission depending on the combination of respective light emission wavelength.

(Electron Blocking Layer)

An electron blocking layer in the present invention comprises a hole transporting material. The hole transporting material is not particularly limited, as far as the hole transporting material has a function to transport a hole injected from an anode to an unit light emitting layer nearest to the anode and to prevent the electron from passing through to the anode side from the unit light emitting layer. The electron blocking layer preferably comprises a light emitting material from view points of improving high emitting efficiency and long driving durability.

It is preferred that a thickness of the electron blocking layer is generally 3 nm to 100 nm in order to lower driving voltage, more preferably it is 5 nm to 30 nm, and further preferably it is 10 nm to 20 nm. In a case where the thickness exceeds 100 nm, migration of a hole is hindered greatly to result in a problem of increasing driving voltage, which is not preferred. In a case where the thickness is less than 3 nm, the layer is not formed sufficiently and partially or entirely loses the function as the electron blocking layer, which is not preferred.

(Hole Blocking Layer)

A hole blocking layer in the present invention comprises an electron transporting material. The electron transporting material is not particularly limited, as far as the electron transporting material has a function to transport an electron injected from a cathode to an unit light emitting layer nearest to the cathode and to prevent the holes from passing through to the cathode side from the unit light emitting layer. The hole blocking layer preferably comprises a light emitting material from view points of improving high emitting efficiency and long driving durability.

It is preferred that a thickness of the hole blocking layer is generally 3 nm to 100 nm in order to lower driving voltage, more preferably it is 5 nm to 30 nm, and further preferably it is 10 nm to 20 nm. In a case where the thickness exceeds 100 nm, migration of electron is hindered greatly to result in a problem of increasing the driving voltage, which is not preferred. In a case where the thickness is less than 3 nm, the layer is not formed sufficiently and partially or entirely loses the function as the hole blocking layer, which is not preferred.

### (Layer Constitution)

The layer constitution is to be described with reference to the drawings. In the illustrated constitution, only the layers necessary for describing the intension of the present application are shown. Those element necessary for the light emitting device but not necessary directly for the explanation of the invention are omitted.

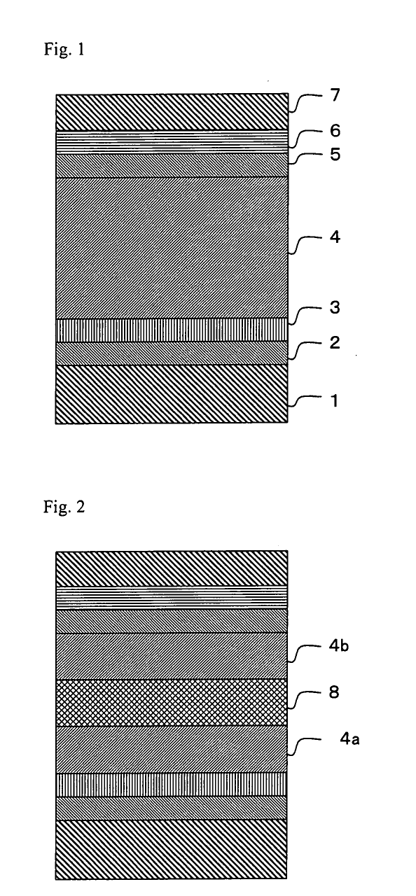

FIG. 1 is a schematic view for the layer constitution of a comparative light emitting device. An anode electrode 1 comprising ITO, etc. is present on a substrate (not illustrated), on which a hole injection layer 2, a hole transport layer 3, a light emitting layer 4, an electron transport layer 5, an electron injection layer 6, and a cathode 7 made of a metal such as aluminum are disposed orderly.

FIG. 2 shows an example of a light emitting device of the invention in which a light emitting layer is bisected into a first light emitting layer 4a and a second light emitting layer 4b, and an intermediate layer 8 is disposed therebetween. The total thickness including two light emitting layers 4a, 4b and an intermediate layer 8 is substantially identical with that for the light emitting layer 4 in FIG. 1.

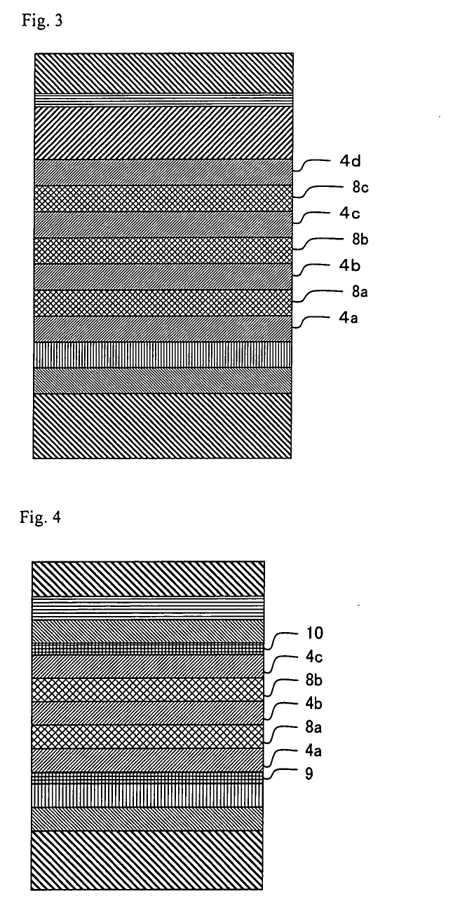

FIG. 3 shows another example of the layer constitution of the invention. The light emitting layer is divided into four portions 4a, 4b, 4c and 4d and each of intermediate layers 8a, 8b, and 8c is disposed between each of the divided light emitting layers. The total thickness including the divided four light emitting layers 4a, 4b, 4c and 4d and three intermediate layers 8a, 8b, and 8c is substantially equal with that for the light emitting layer in FIG. 1.

FIG. 4 shows another example of the layer constitution of the invention. The light emitting layer is divided into three portions 4a, 4b and 4c, each of intermediate layers 8a and 8b is disposed between each of the divided light emitting layers, and an electron blocking layer 9 between the unit light emitting layer 4a and a hole transport layer 3, and a hole blocking layer 10 between the unit light emitting layer 4c and an electron transport layer 5 are disposed. The total thickness including the divided three light emitting layers 4a, 4b and 4c, two intermediate layers 8a and 8b, the electron blocking layer 9 and the hole blocking layer 10 is substantially equal with that for the light emitting layer in FIG. 1.

### 2. Organic Electroluminescence Device

Each of the constituent elements constituting the organic electroluminescence device used in the invention is to be described more specifically.

The organic electroluminescence device in the invention preferably has a resonator structure in which a plurality of thin organic compound layers are present between the cathode and the anode.

One of preferred embodiments of the invention comprises, on a transparent substrate, a multi-layered film mirror comprising a plurality of stacked films of different reflective indexes, a transparent or semi-transparent electrode, a light emitting layer, and a metal electrode stacked to each other. The light generated in the light emitting layer repeats reflection and conducts oscillation between the multi-layered film mirror and the metal electrode as reflection plates.

In another preferred embodiment of the invention, a transparent or semi-transparent electrode and a metal electrode function respectively as reflection plates on a transparent substrate in which light generated in the light emitting layer repeats reflection and conducts oscillation therebetween.

For forming the resonance structure, an optical channel length determined based on the effective refractive index of two reflection plates, and the refractive index and the thickness for each of the layers between the reflection plates are controlled to optimal values for obtaining a desired resonance wavelength. A calculation formula in a case of the first embodiment is described in the specification of JP-A No. 9-180883 and the calculation formula in a case of the second embodiment is described in the specification of JP-A No. 2004-127795.

As a lamination pattern of the organic compound layers according to the present invention, it is preferred that the layers are laminated in the order of a hole injection layer, a light emitting layer, and electron transport layer from the anode side. Moreover, a hole transport layer between the hole injection layer and the light emitting layer and/or an electron transporting intermediate layer between the light emitting layer and the electron transport layer may be provided. In addition, a hole transporting intermediate layer may be provided in between the light emitting layer and the hole transport layer, and similarly, an electron injection layer may be provided in between the cathode and the electron transport layer.

The preferred modes of the organic compound layer in the organic electroluminescence device of the present invention are as follows. (1) An embodiment having a hole injection layer, a hole transport layer (the hole injection layer may also have the role of the hole transport layer), a hole transporting intermediate layer, a light emitting layer, an electron transport layer, and an electron injection layer (the electron transport layer may also have the role of the electron injection layer) in this order from the anode side; (2) an embodiment having a hole injection layer, a hole transport layer (the hole injection layer may also have the role of the hole transport layer), a light emitting layer, an electron transporting immediate layer, an electron transport layer, and an electron injection layer (the electron transport layer may also have the role of the electron injection layer); and (3) an embodiment having a hole injection layer, a hole transport layer (the hole injection layer may also have the role of the hole transport layer), a hole transporting intermediate layer, a light emitting layer, an electron transporting intermediate layer, an electron transport layer, and an electron injection layer (the electron transport layer may also have the role of the electron injection layer).

A light emitting layer in the present invention is divided into plural thin layers in the thickness direction thereof, and an intermediate layer is positioned between each of the divided layers of the light emitting layer. Preferably, an electron blocking layer between a light emitting layer and an anode, and a hole blocking layer between a light emitting layer and a cathode are provided.

The above-described hole transporting intermediate layer preferably has at least either a function for accelerating the injection of holes into the light emitting layer, or a function for blocking electrons.

Furthermore, the above-described electron transporting intermediate preferably layer has at least either a function for accelerating the injection of electrons into the light emitting layer, or a function for blocking holes.

Moreover, at least either of the above-described hole transporting intermediate layer and the electron transporting intermediate layer preferably has a function for blocking excitons produced in the light emitting layer.

In order to realize effectively the functions for accelerating the injection of hole, or the injection of electrons, and the functions for blocking holes, electrons, or excitons, it is preferred that the hole transporting intermediate layer and the electron transporting intermediate layer are adjacent to the light emitting layer.

The respective layers mentioned above may be separated into a plurality of secondary layers.

Next, the components constituting the electroluminescence device of the present invention will be described in detail.

An organic compound layer according to the present invention will be described.

The organic electroluminescence device of the present invention has at least one organic compound layer including a light emitting layer. Examples of the organic compound layers other than the light emitting layer include, as mentioned above, respective layers of a hole injection layer, a hole transport layer, a hole transporting intermediate layer, a light emitting layer, an electron transporting intermediate layer, an electron transport layer, an electron injection layer and the like.

The respective layers that constitute organic compound layers in the present invention can be preferably formed by any method of dry layering methods such as a vapor deposition method and a sputtering method, a transferring method, a printing method, a coating method, a ink jet method, or a spray method.

(Light Emitting Layer)

The light emitting layer is a layer having a function for receiving holes from the anode, the hole injection layer, the hole transport layer or the hole transporting buffer layer, and receiving electrons from the cathode, the electron injection layer, the electron transport layer, or the electron transporting buffer layer, and for providing a field for recombination of the holes with the electrons to emit a light.

The light emitting layer of the present invention contains at least one type of luminescent dopant and a plurality of host compounds.

The light emitting layer may be composed of either one layer or two or more layers wherein the respective layers may emit light of different colors from one another in the respective layers. Even if the light emitting layers are composed of a plurality thereof, it is preferred that each of the light emitting layers contains at least one luminescent dopant and a plurality of host compounds.

The luminescent dopant and the plural host compounds contained in the light emitting layer of the present invention may be either a combination of a fluorescence luminescent dopant in which the luminescence (fluorescence) from a singlet exciton is obtained and the plurality of host compounds, or a combination of a phosphorescence luminescent dopant in which the luminescence (phosphorescence) from triplet exciton is obtained and the plurality of host compounds; among these, a combination of the phosphorescence luminescent dopant and the plurality of host compounds is preferable in view of luminescent efficiency.

The light emitting layer of the present invention may contain two or more types of luminescent dopants for improving color purity and expanding the luminescent wavelength region.

Any of phosphorescent emission materials, fluorescent emission materials and the like may be used as the luminescent dopant in the present invention.

It is preferred that the luminescent dopant in the present invention is one satisfying a relationship between the above-described host compound and the luminescent dopant of 1.2 eV>ΔIp>0.2 eV and/or 1.2 eV>ΔEa>0.2 eV in view of driving durability.

<<Phosphorescence Luminescent Dopant>>

The phosphorescent emission material used in the present invention is not particularly limited, but an ortho-metal complex or a porphyrin metal complex is preferred.

The ortho-metal complex referred to herein is a generic designation of a group of compounds described in, for instance, Akio Yamamoto, Yuki Kinzoku Kagaku, Kiso to Oyo (“Organic Metal Chemistry, Fundamentals and Applications”) (Shokabo, 1982), pp. 150 and 232, and H. Yersin, Photochemistry and Photophysics of Coordination Compounds (New York: Springer-Verlag, 1987), pp. 71-77 and pp. 135-146. The ortho-metal complex can be advantageously used as a light emitting material because high brightness and excellent emitting efficiency can be obtained.

As a ligand that forms the ortho-metal complex, various kinds can be cited and are described in the above-mentioned literature as well. Examples of preferable ligands include a 2-phenylpyridine derivative, a 7,8-benzoquinoline derivative, a 2-(2-thienyl)pyridine derivative, a 2-(1-naphtyl)pyridine derivative and a 2-phenylquinoline derivative. The derivatives may be substituted by a substituent as needs arise. Furthermore, the ortho-metal complex may have other ligands than the ligands mentioned above.

An ortho-metal complex used in the present invention can be synthesized according to various kinds of known processes such as those described in Inorg. Chem., 1991, Vol. 30, pp. 1685; Inorg. Chem., 1988, Vol. 27, pp. 3464; Inorg. Chem., 1994, Vol. 33, pp. 545; Inorg. Chim. Acta, 1991, Vol. 181, pp. 245; J. Organomet. Chem., 1987, Vol. 335, pp. 293 and J. Am. Chem. Soc., 1985, Vol. 107, pp. 1431.

Among the ortho-metal complexes, compounds emitting from a triplet exciton can be preferably employed in the present invention from the viewpoint of improving emission efficiency.

Furthermore, among the porphyrin metal complexes, a porphyrin platinum complex is preferable.

The phosphorescent light emitting materials may be used singularly or in a combination of two or more. Furthermore, a fluorescent emission material and a phosphorescent emission material may be simultaneously used.

<<Fluorescence Luminescent Dopant>>

Examples of the above-described fluorescent emission materials include, for example, a benzoxazole derivative, a benzimidazole derivative, a benzothiazole derivative, a styrylbenzene derivative, a polyphenyl derivative, a diphenylbutadiene derivative, a tetraphenylbutadiene derivative, a naphthalimide derivative, a coumarin derivative, a perylene derivative, a perinone derivative, an oxadiazole derivative, an aldazine derivative, a pyralidine derivative, a cyclopentadiene derivative, a bis-styrylanthracene derivative, a quinacridone derivative, a pyrrolopyridine derivative, a thiadiazolopyridine derivative, a styrylamine derivative, aromatic dimethylidene compounds, a variety of metal complexes represented by metal complexes or rare-earth complexes of 8-quinolynol, polymer compounds such as polythiophene, polyphenylene and polyphenylenevinylene, organic silanes, and the like. These compounds may be used singularly or in a combination of two or more.

Among these, specific examples of the luminescent dopants include the following compounds, but it should be noted that the present invention is not limited thereto.

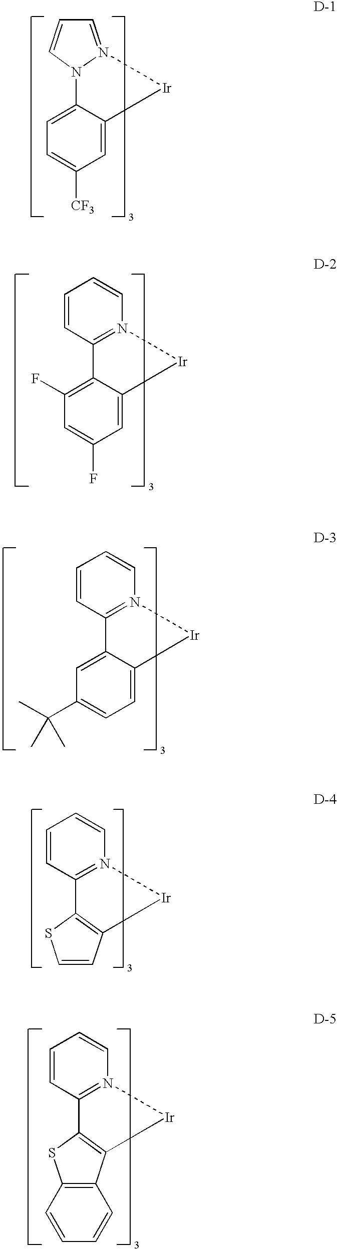

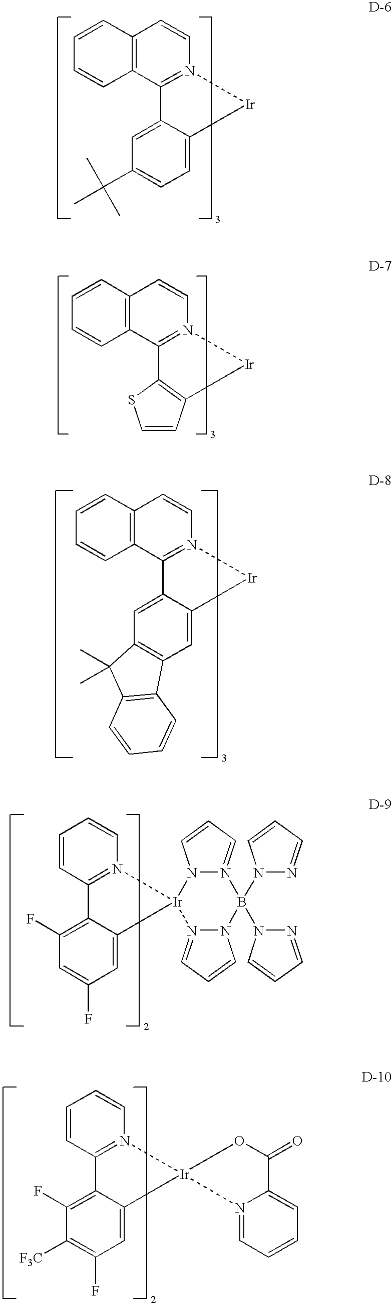

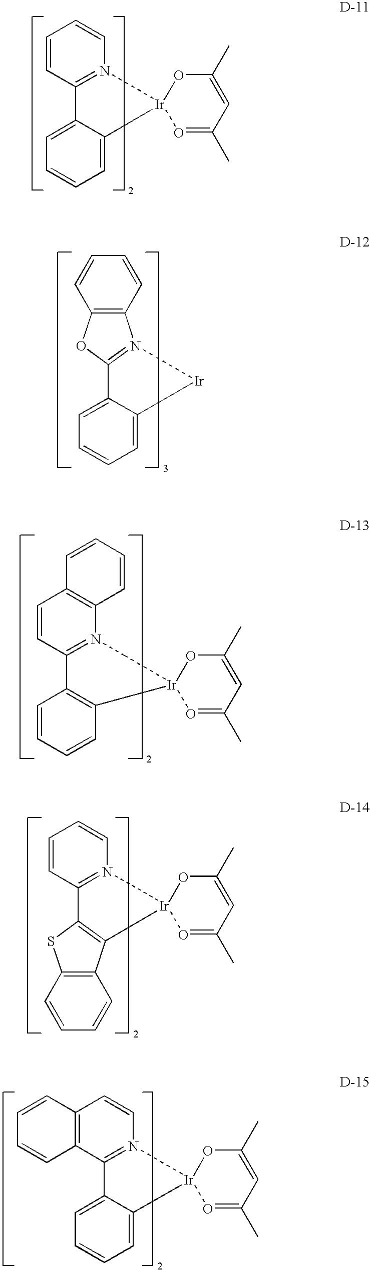

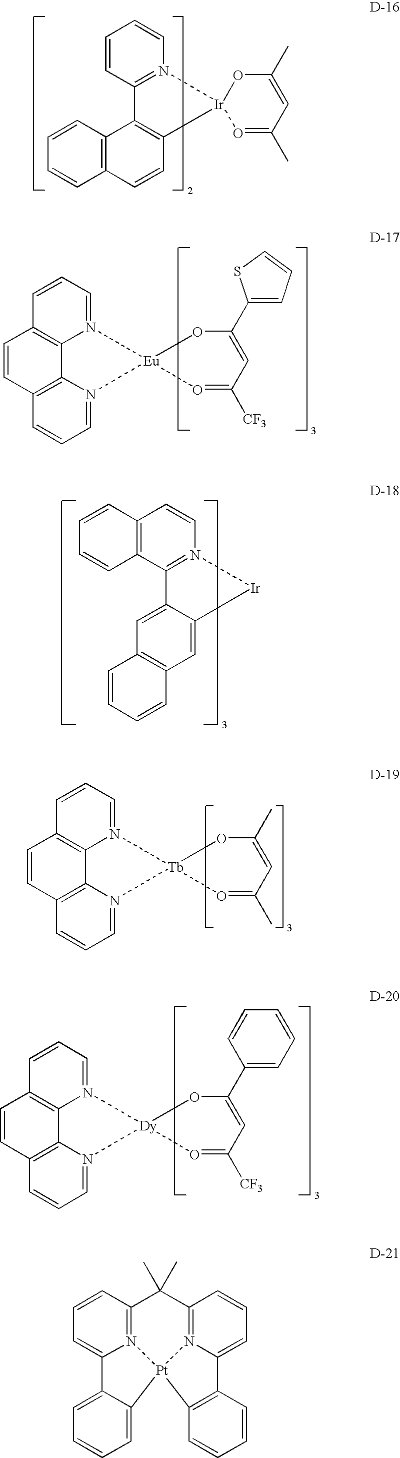

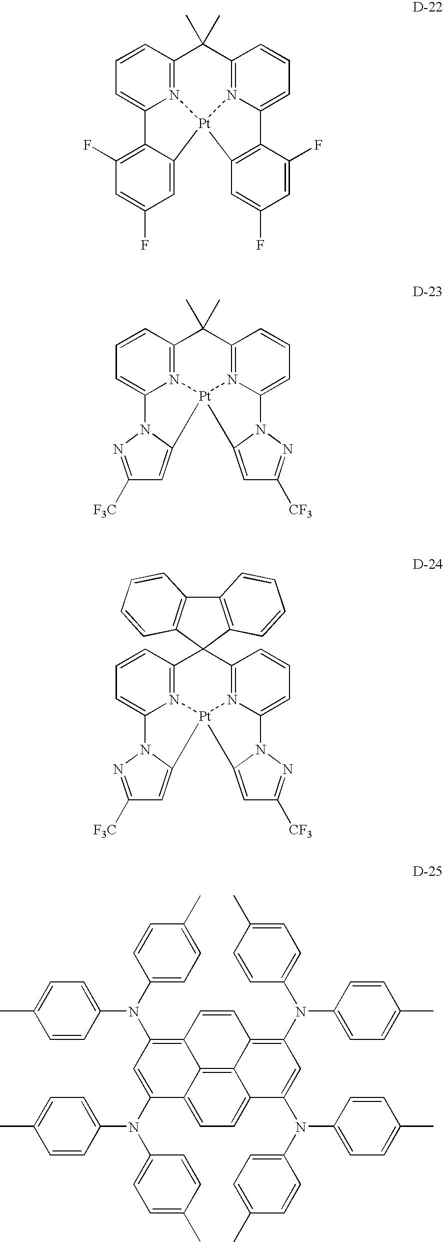

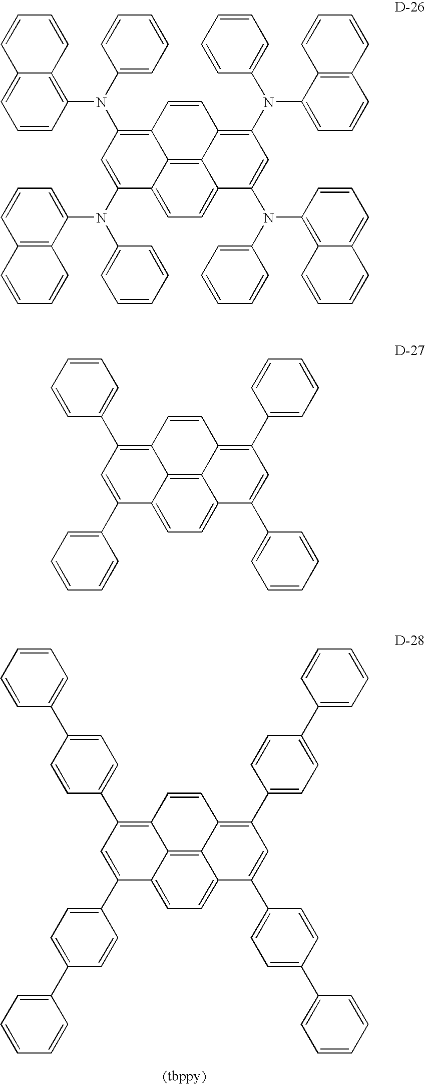

Among the above-described compounds, as the luminescent dopants to be used according to the present invention, D-2, D-3, D-4, D-5, D-6, D-7, D-8, D-9, D-10, D-11, D-12, D-13, D-14, D-15, D-16, D-21, D-22, D-23, D-24, or D-25 to D-28 is preferable, D-2, D-3, D-4, D-5, D-6, D-7, D-8, D-12, D-14, D-15, D-16, D-21, D-22, D-23, D-24, or D-25 to D-28 is more preferable, and D-21, D-22, D-23, D-24, or D-25 to D-28 is further preferable in view of luminescent efficiency, and durability.

The luminescent dopant in a light emitting layer is contained in an amount of 0.1% by mass to 30% by mass with respect to the total mass of the compounds generally forming the light emitting layer, but it is preferably contained in an amount of 1% by mass to 15% by mass, and more preferably in an amount of 2% by mass to 12% by mass in view of durability and luminescent durability.

(Host Material)

As the host materials to be used according to the present invention, hole transporting host materials excellent in hole transporting property (referred to as a “hole transporting host” in some cases) and electron transporting host compounds excellent in electron transporting property (referred to as an “electron transporting host” in some cases) may be used.

<<Hole Transporting Host>>

The hole transporting host used for the organic layer of the present invention preferably has an ionization potential Ip of 5.1 eV to 6.4 eV, more preferably has an ionization potential of 5.4 eV to 6.2 eV, and further preferably has an ionization potential of 5.6 eV to 6.0 eV in view of improvements in durability and decrease in driving voltage. Furthermore, it preferably has an electron affinity Ea of 1.2 eV to 3.1 eV, more preferably of 1.4 eV to 3.0 eV, and further preferably of 1.8 eV to 2.8 eV in view of improvements in durability and decrease in driving voltage.

Specific examples of such hole transporting hosts as mentioned above include pyrrole, carbazole, triazole, oxazole, oxadiazole, pyrazole, imidazole, polyarylalkane, pyrazoline, pyrazolone, phenylenediamine, arylamine, amino-substituted chalcone, styrylanthracene, fluorenone, hydrazone, stilbene, silazane, aromatic tertiary amine compounds, styrylamine compounds, aromatic dimethylidine compounds, porphyrin compounds, polysilane compounds, poly(N-vinylcarbazole), aniline copolymers, electroconductive high-molecular oligomers such as thiophene oligomers, polythiophenes and the like, organic silanes, carbon films, derivatives thereof, and the like.

Among these, carbazole derivatives, aromatic tertiary amine compounds, and thiophene derivatives are preferable, and particularly, compounds containing a plurality of carbazole skeletons and/or aromatic tertiary amine skeletons in a molecule are preferred.

As specific examples of the hole transporting hosts described above, the following compounds may be listed, but the present invention is not limited thereto.

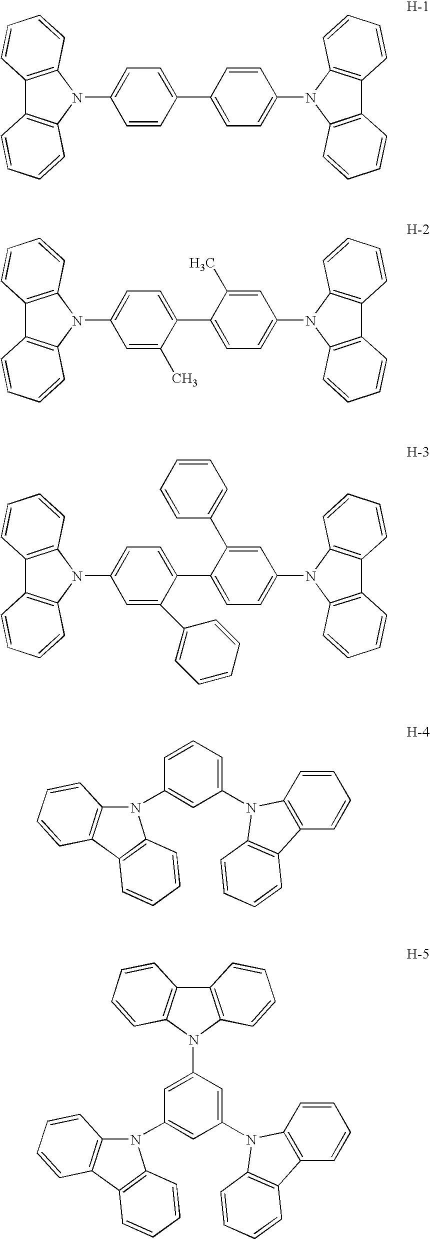

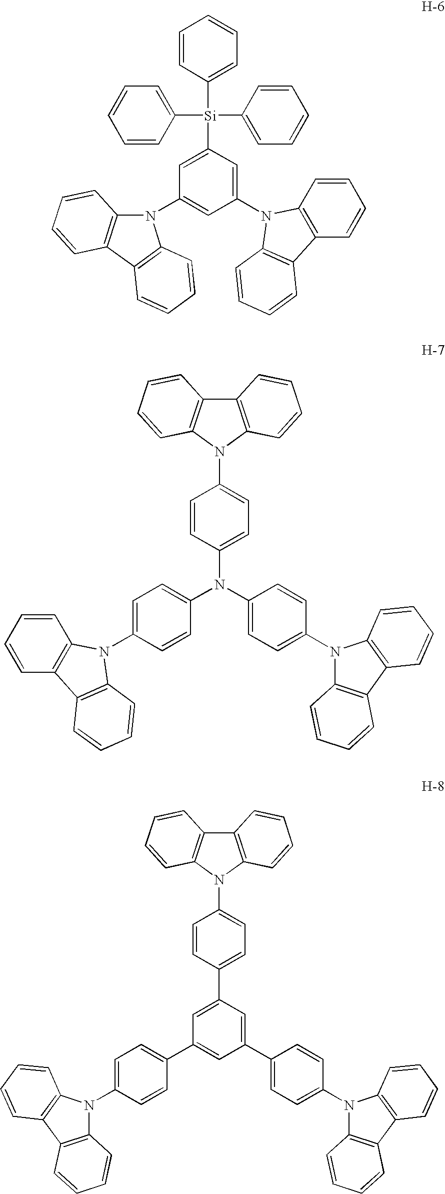

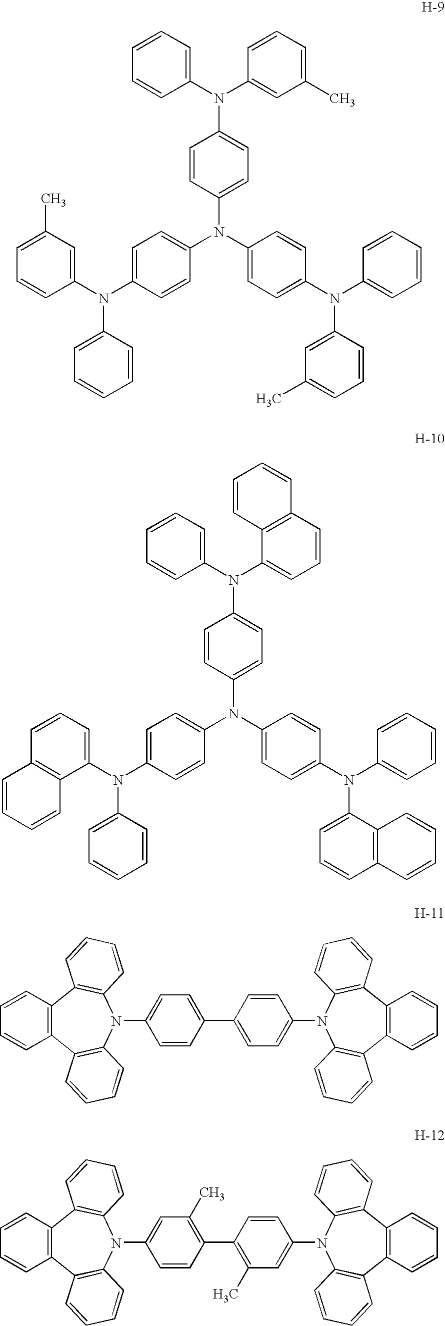

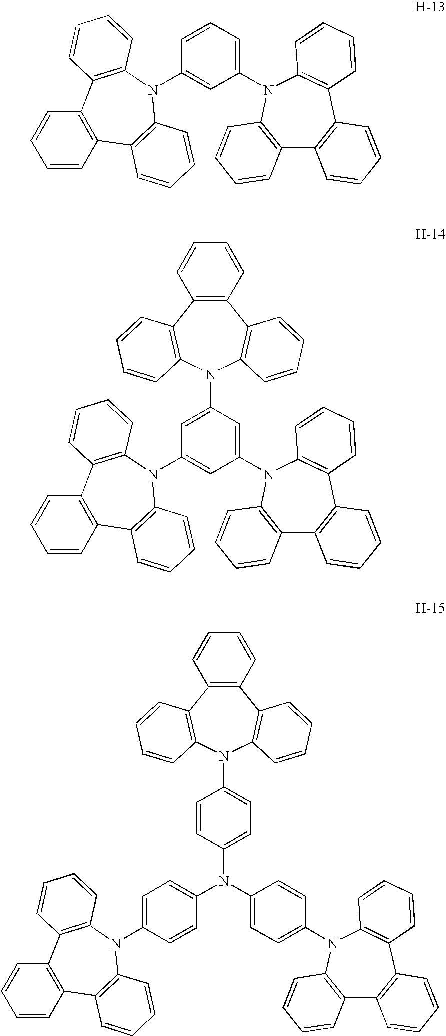

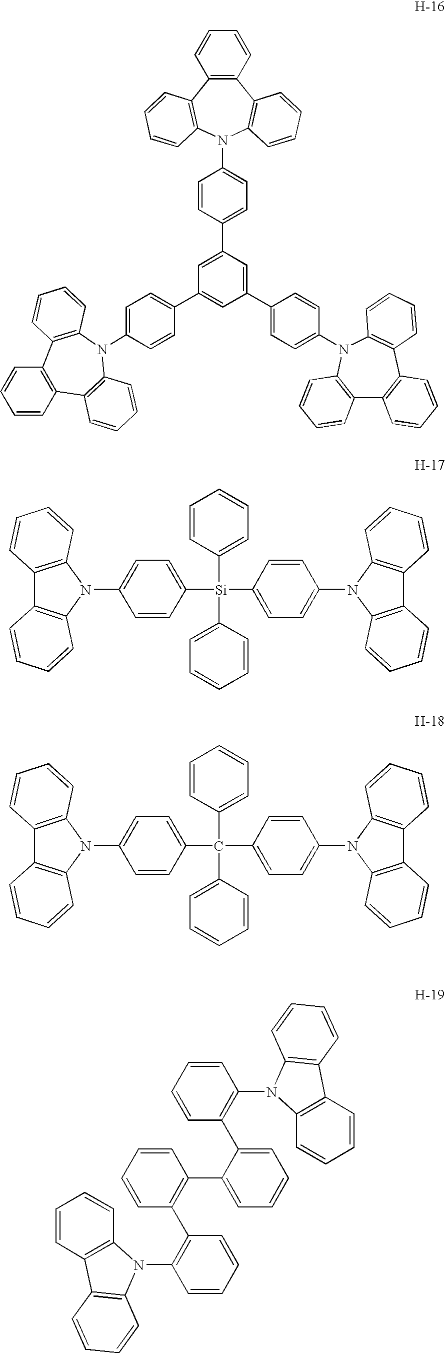

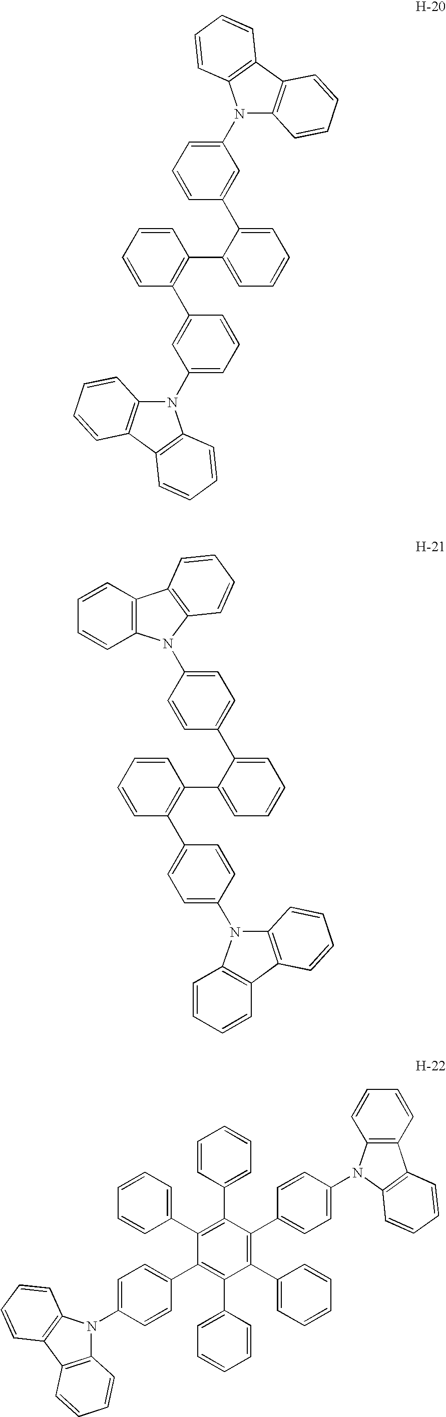

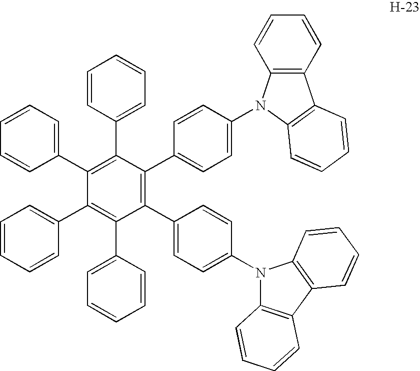

<<Electron Transporting Host>>

As the electron transporting host used according to the present invention, it is preferred that an electron affinity Ea of the host is 2.5 eV to 3.5 eV, more preferably 2.6 eV to 3.4 eV, and further preferably 2.8 eV to 3.3 eV in view of improvements in durability and decrease in driving voltage. Furthermore, it is preferred that an ionization potential Ip of the host is 5.7 eV to 7.5 eV, more preferably 5.8 eV to 7.0 eV, and further preferably 5.9 eV to 6.5 eV in view of improvements in durability and decrease in driving voltage.

Specific examples of such electron transporting hosts as mentioned above include pyridine, pyrimidine, triazine, imidazole, pyrazole, triazole, oxazole, oxadiazole, fluorenone, anthraquinonedimethane, anthrone, diphenylquinone, thiopyrandioxide, carbodiimide, fluorenylidenemethane, distyrylpyradine, fluorine-substituted aromatic compounds, heterocyclic tetracarboxylic anhydrides such as naphthaleneperylene and the like, phthalocyanine, derivatives thereof (which may form a condensed ring with another ring), and a variety of metal complexes represented by metal complexes of 8-quinolynol derivatives, metal phthalocyanine, and metal complexes having benzoxazole or benzothiazole as the ligand.

Preferable electron transporting hosts are metal complexes, azole derivatives (benzimidazole derivatives, imidazopyridine derivatives and the like), and azine derivatives (pyridine derivatives, pyrimidine derivatives, triazine derivatives and the like). Among these, metal complexes are preferred according to the present invention in view of durability. As the metal complex compound, a metal complex containing a ligand having at least one nitrogen atom, oxygen atom, or sulfur atom to be coordinated with the metal is more preferable.

Although a metal ion in the metal complex is not particularly limited, a beryllium ion, a magnesium ion, an aluminum ion, a gallium ion, a zinc ion, an indium ion, a tin ion, a platinum ion, or a palladium ion is preferred; more preferable is a beryllium ion, an aluminum ion, a gallium ion, a zinc ion, a platinum ion, or a palladium ion; and further preferable is an aluminum ion, a zinc ion, or a palladium ion.

Although there are a variety of well-known ligands to be contained in the above-described metal complexes, examples thereof include ligands described in “Photochemistry and Photophysics of Coordination Compounds” authored by H. Yersin, published by Springer-Verlag Company in 1987; “YUHKI KINZOKU KAGAKU—KISO TO OUYOU— (Metalorganic Chemistry—Fundamental and Application—)” authored by Akio Yamamoto, published by Shokabo Publishing Co., Ltd. in 1982, and the like.

The ligands are preferably nitrogen-containing heterocyclic ligands (having preferably 1 to 30 carbon atoms, more preferably 2 to 20 carbon atoms, and particularly preferably 3 to 15 carbon atoms); and they may be a unidentate ligand or a bi- or higher-dentate ligand. Preferable are bi- to hexa-dentate ligands, and mixed ligands of bi- to hexa- dentate ligands with a unidentate ligand are also preferable.

Examples of the ligands include azine ligands (e.g. pyridine ligands, bipyridyl ligands, terpyridine ligands and the like); hydroxyphenylazole ligands (e.g. hydroxyphenylbenzimidazole ligands, hydroxyphenylbenzoxazole ligands, hydroxyphenylimidazole ligands, hydroxyphenylimidazopyridine ligands and the like); alkoxy ligands (those having preferably 1 to 30 carbon atoms, more preferably 1 to 20 carbon atoms, and particularly preferably 1 to 10 carbon atoms, examples of which include methoxy, ethoxy, butoxy, 2-ethylhexyloxy and the like); aryloxy ligands (those having preferably 6 to 30 carbon atoms, more preferably 6 to 20 carbon atoms, and particularly preferably 6 to 12 carbon atoms, examples of which include phenyloxy, 1-naphthyloxy, 2-naphthyloxy, 2,4,6-trimethylphenyloxy, 4-biphenyloxy and the like); heteroaryloxy ligands (those having preferably 1 to 30 carbon atoms, more preferably 1 to 20 carbon atoms, and particularly preferably 1 to 12 carbon atoms, examples of which include pyridyloxy, pyrazyloxy, pyrimidyloxy, quinolyloxy and the like); alkylthio ligands (those having preferably 1 to 30 carbon atoms, more preferably 1 to 20 carbon atoms, and particularly preferably 1 to 12 carbon atoms, examples of which include methylthio, ethylthio and the like); arylthio ligands (those having preferably 6 to 30 carbon atoms, more preferably 6 to 20 carbon atoms, and particularly preferably 6 to 12 carbon atoms, examples of which include phenylthio and the like); heteroarylthio ligands (those having preferably 1 to 30 carbon atoms, more preferably 1 to 20 carbon atoms, and particularly preferably 1 to 12 carbon atoms, examples of which include pyridylthio, 2-benzimidazolylthio, 2-benzooxazolylthio, 2-benzothiazolylthio and the like); siloxy ligands (those having preferably 1 to 30 carbon atoms, more preferably 3 to 25 carbon atoms, and particularly preferably 6 to 20 carbon atoms, examples of which include a triphenylsiloxy group, a triethoxysiloxy group, a triisopropylsiloxy group and the like); aromatic hydrocarbon anion ligands (those having preferably 6 to 30 carbon atoms, more preferably 6 to 25 carbon atoms, and particularly preferably 6 to 20 carbon atoms, examples of which include a phenyl anion, a naphthyl anion, an anthranyl anion and the like anion); aromatic heterocyclic anion ligands (those having preferably 1 to 30 carbon atoms, more preferably 2 to 25 carbon atoms, and particularly preferably 2 to 20 carbon atoms, examples of which include a pyrrole anion, a pyrazole anion, a triazole anion, an oxazole anion, a benzoxazole anion, a thiazole anion, a benzothiazole anion, a thiophene anion, a benzothiophene anion and the like); indolenine anion ligands and the like. Among these, nitrogen-containing heterocyclic ligands, aryloxy ligands, heteroaryloxy groups, aromatic hydrocarbon anion ligands, aromatic heterocyclic anion ligands or siloxy ligands are preferable, and nitrogen-containing heterocyclic ligands, aryloxy ligands, siloxy ligands, aromatic hydrocarbon anion ligands, or aromatic heterocyclic anion ligands are more preferable.

Examples of the metal complex electron transporting hosts include compounds described, for example, in Japanese Patent Application Laid-Open Nos. 2002-235076, 2004-214179, 2004-221062, 2004-221065, 2004-221068, 2004-327313 and the like.

Specific examples of these electron transporting hosts include the following materials, but it should be noted that the present invention is not limited thereto.

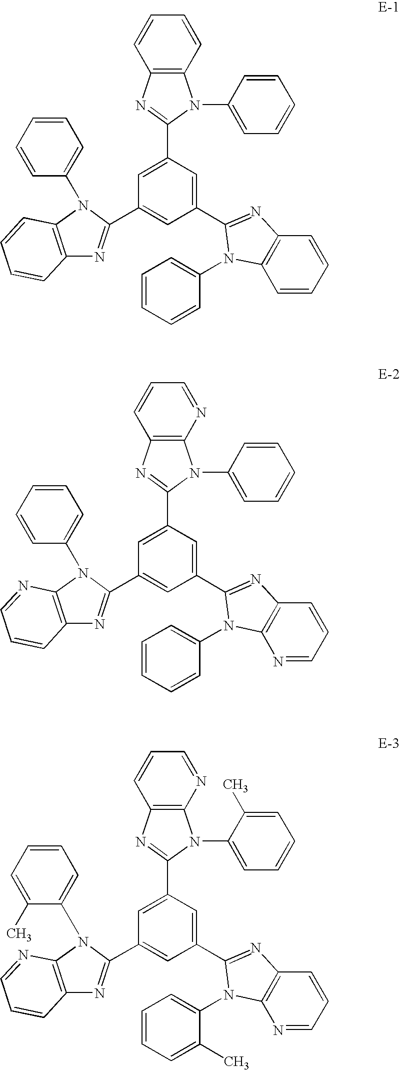

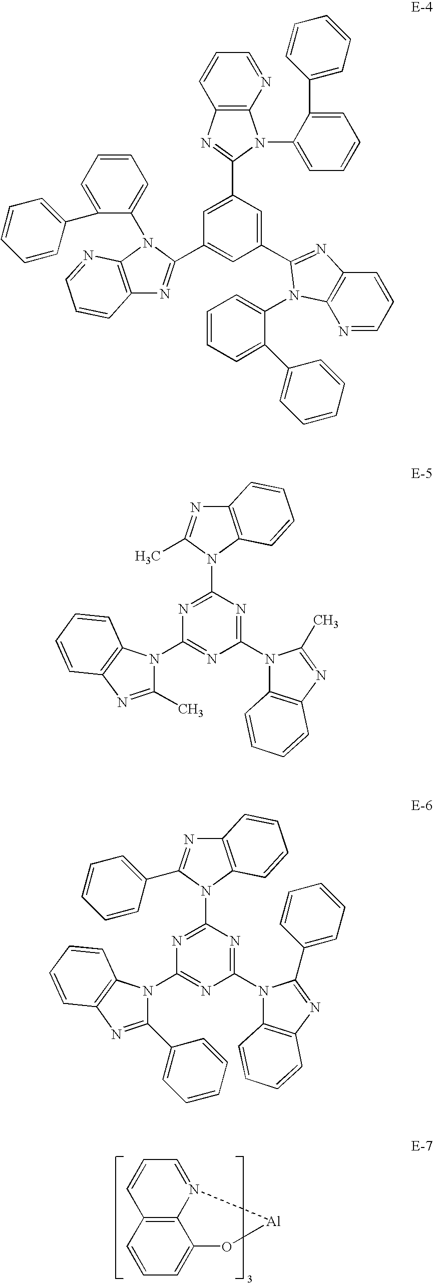

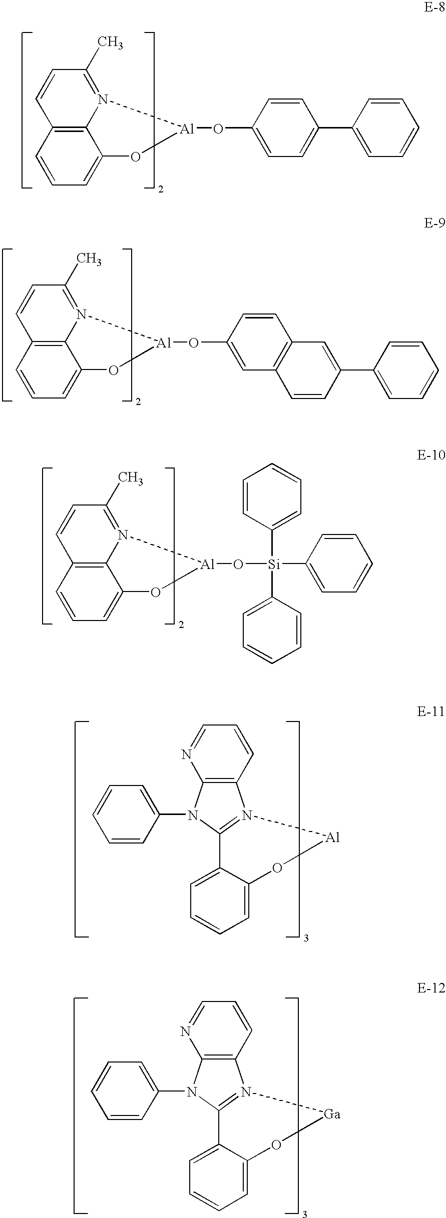

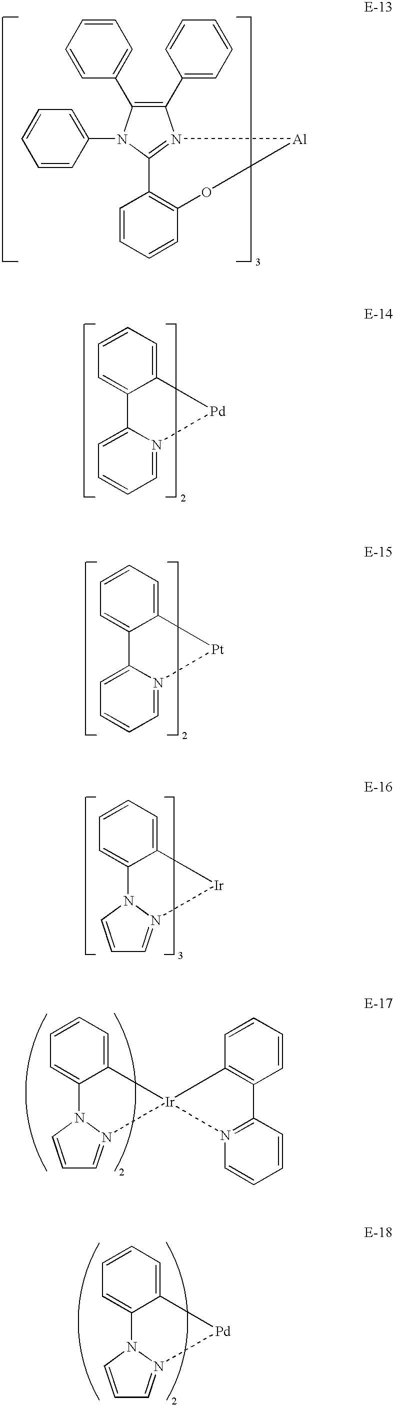

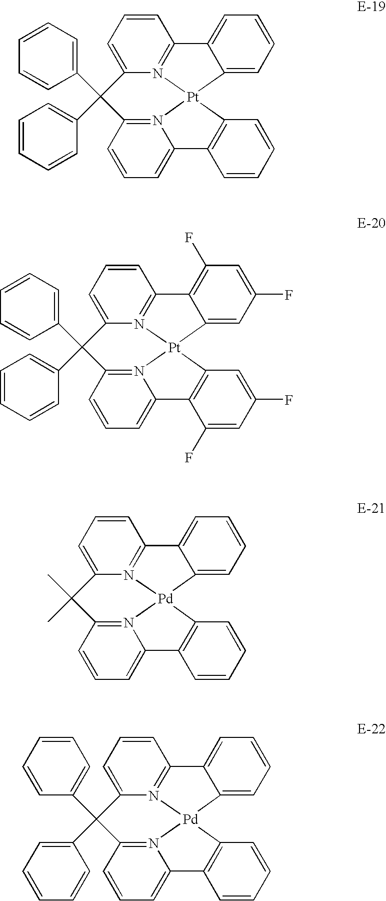

As the electron transportation hosts, E-1 to E-6, E-8, E-9, E-10, E-21, or E-22 is preferred, E-3, E-4, E-6, E-8, E-9, E-10, E-21, or E-22 is more preferred, and E-3, E-4, E-21, or E-22 is further preferred.

In the light emitting layer of the present invention, it is preferred that when a phosphorescence luminescent dopant is used as the luminescent dopant, the lowest triplet excitation energy T1(D) in the phosphorescence luminescent dopant and the minimum value among the lowest triplet excitation energies T1(H) min in the plural host compounds satisfy the relationship of T1(H)min>T1(D) in view of color purity, luminescent efficiency, and driving durability.

Although a content of the host compounds according to the present invention is not particularly limited, it is preferably 15% by mass to 85% by mass with respect to the total mass of the compounds forming the light emitting layer in view of luminescence efficiency and driving voltage.

A carrier mobility in the light emitting layer is generally from 10⁻⁷ cm².V⁻¹.s⁻¹ to 10⁻¹ cm².V⁻¹.s⁻¹, and within this range, it is preferably from 10⁻⁶ cm².V⁻¹.s⁻¹ to 10⁻¹ cm².V⁻¹.s⁻¹, further preferably, from 10⁻⁵ cm².V⁻¹.s⁻¹ to 10⁻¹ cm².V⁻¹.s⁻¹, and particularly preferably, from 10⁻⁴ cm².V⁻¹.s⁻¹ to 10⁻¹ cm².V⁻¹.s⁻¹ in view of luminescence efficiency.

It is preferred that the carrier mobility of the light emitting layer is lower than that of the carrier transportation layer, which will be mentioned herein below, in view of luminescence efficiency and driving durability.

The carrier mobility is measured in accordance with the “Time of Flight” method, and the resulting value is determined to be the carrier mobility.

(Hole Injection Layer and Hole Transport Layer)

The hole injection layer and hole transport layer correspond to layers functioning to receive holes from an anode or from an anode side and to transport the holes to a cathode side.

As an electron-accepting dopant to be introduced into a hole injection layer or a hole transport layer, either of an inorganic compound or an organic compound may be used as long as the compound has electron accepting property and a function for oxidizing an organic compound. Specifically, inorganic compounds such as halides compounds, for example, ferric chloride, aluminum chloride, gallium chloride, indium chloride, antimony pentachloride and the like, and metal oxides such as vanadium pentaoxide, molybdenum trioxide and the like are preferably used as the inorganic compounds.

In case of the organic compounds, compounds having substituents such as a nitro group, a halogen, a cyano group, or a trifluoromethyl group; quinone compounds, acid anhydride compounds, and fullerenes may be preferably applied.

Specific examples of the organic compounds include hexacyanobutadiene, hexacyanobenzene, tetracyanoethylene, tetracyanoquinodimethane, tetrafluorotetracyanoquinodimethane, p-fluoranil, p-chloranil, p-bromanil, p-benzoquinone, 2,6-dichlorobenzoquinone, 2,5-dichlorobenzoquinone, tetramethylbenzoquinone, 1,2,4,5-tetracyanobenzene, o-dicyanobenzene, p-dicyanobenzene, 1,4-dicyanotetrafluorobenzene, 2,3-dichloro-5,6-dicyanobenzoquinone, p-dinitrobenzene, m-dinitrobenzene, o-dinitrobenzene, p-cyanonitrobenzene, m-cyanonitrobenzene, o-cyanonitrobenzene, 1,4-naphthoquinone, 2,3-dichloronaphthoquinone, 1-nitronaphthalene, 2-nitronaphthalene, 1,3-dinitronaphthalene, 1,5-dinitronaphthalene, 9-cyanoanthoracene, 9-nitroanthracene, 9,10-anthraquinone, 1,3,6,8-tetranitrocarbazole, 2,4,7-trinitro-9-fluorenone, 2,3,5,6-tetracyanopyridine, maleic anhydride, phthalic anhydride, fullerene C60, and fullerene C70. Other specific examples include materials described in patent documents such as JP-A Nos. 6-212153, 11-111463, 11-251067, 2000-196140, 2000-286054, 2000-315580, 2001-102175, 2001-160493, 2002-252085, 2002-56985, 2003-157981, 2003-217862, 2003-229278, 2004-342614, 2005-72012, 2005-166637, 2005-209643 and the like.

Among these, hexacyanobutadiene, hexacyanobenzene, tetracyanoethylene, tetracyanoquinodimethane, tetrafluorotetracyanoquinodimethane, p-fluoranil, p-chloranil, p-bromanil, p-benzoquinone, 2,6-dichlorobenzoquinone, 2,5-dichlorobenzoquinone, 1,2,4,5-tetracyanobenzene, 1,4-dicyanotetrafluorobenzene, 2,3-dichloro-5,6-dicyanobenzoquinone, p-dinitrobenzene, m-dinitrobenzene, o-dinitrobenzene, 1,4-naphthoquinone, 2,3-dichloronaphthoquinone, 1,3-dinitronaphthalene, 1,5-dinitronaphthalene, 9,10-anthraquinone, 1,3,6,8-tetranitrocarbazole, 2,4,7-trinitro-9-fluorenone, 2,3,5,6-tetracyanopyridine, or fullerene C60 is preferable. Hexacyanobutadiene, hexacyanobenzene, tetracyanoethylene, tetracyanoquinodimethane, tetrafluorotetracyanoquinodimethane, p-fluoranil, p-chloranil, p-bromanil, 2,6-dichlorobenzoquinone, 2,5-dichlorobenzoquinone, 2,3-dichloronaphthoquinone, 1,2,4,5-tetracyanobenzene, 2,3-dichloro-5,6-dicyanobenzoquinone, or 2,3,5,6-tetracyanopyridine is particularly preferred, and tetrafluorotetracyanoquinodimethane is most particularly preferred.

These electron-accepting dopants may be used alone or in a combination of two or more of them.

Although an applied amount of these electron-accepting dopants depends on the type of material, 0.01% by mass to 50% by mass of a dopant is preferred with respect to a hole transport layer material, 0.05% by mass to 20% by mass is more preferable, and 0.1% by mass to 10% by mass is particularly preferred. When the amount applied is less than 0.01% by mass with respect to the hole transportation material, it is not desirable because the advantageous effects of the present invention are insufficient, and when it exceeds 50% by mass, hole transportation ability is deteriorated, and thus, this is not preferred.

In a case where the hole injection layer contains an acceptor, it is preferred that the hole transport layer has no substantial acceptor.

As a material for the hole injection layer and the hole transport layer, it is preferred to contain specifically pyrrole derivatives, carbazole derivatives, pyrazole derivatives, triazole derivatives, oxazole derivatives, oxadiazole derivatives, imidazole derivatives, polyarylalkane derivatives, pyrazoline derivatives, pyrazolone derivatives, phenylenediamine derivatives, arylamine derivatives, amino-substituted calcon derivatives, styrylanthracene derivatives, fluorenone derivatives, hydrazone derivatives, stilbene derivatives, silazane derivatives, aromatic tertiary amine compounds, styrylamine derivatives, aromatic dimethylidine compounds, porphyrin compounds, organosilane derivatives, carbon or the like.

Although a thickness of the hole injection layer and the hole transport layer is not particularly limited, it is preferred that the thickness is 1 nm to 5 μm, it is more preferably 5 nm to 1 μm, and 10 nm to 500 nm is particularly preferred in view of decrease in driving voltage, improvements in luminescent efficiency, and improvements in durability.

The hole injection layer and the hole transport layer may be composed of a monolayered structure comprising one or two or more of the above-mentioned materials, or a multilayer structure composed of plural layers of a homogeneous composition or heterogeneous compositions.

When the carrier transportation layer adjacent to the light emitting layer is a hole transport layer, it is preferred that the Ip (HTL) of the hole transport layer is smaller than the Ip (D) of the dopant contained in the light emitting layer in view of driving durability.

The Ip (HTL) in the hole transport layer may be measured in accordance with the below-mentioned measuring method of Ip.

A carrier mobility in the hole transport layer is usually from 10⁻⁷ cm².V⁻¹.s⁻¹ to 10⁻¹ cm².V⁻¹.s⁻¹; and in this range, from 10⁻⁵ cm².V⁻¹.s⁻¹ to 10⁻¹ cm².V⁻¹.s⁻¹ is preferable; from 10⁻⁴ cm².V⁻¹.s⁻¹ to 10⁻¹ cm².V⁻¹.s⁻¹ is more preferable; and from 10⁻³ cm².V⁻¹.s⁻¹ to 10⁻¹ cm².V⁻¹.s⁻¹ is particularly preferable in view of the luminescent efficiency.

For the carrier mobility, a value measured in accordance with the same method as that of the carrier mobility of the above-described light emitting layer is adopted.

Moreover, it is preferred that the carrier mobility in the hole transport layer is higher than that in the above-described light emitting layer in view of driving durability and luminescent efficiency.

(Electron Injection Layer and Electron Transport Layer)

The electron injection layer and the electron transport layer are layers having any of functions for injecting electrons from the cathode, transporting electrons, and becoming a barrier to holes which could be injected from the anode.

As a material applied for the electron-donating dopant with respect to the electron injection layer or the electron transport layer, any material may be used as long as it has an electron-donating property and a property for reducing an organic compound, and alkaline metals such as Li, alkaline earth metals such as Mg, and transition metals including rare-earth metals are preferably used.

Particularly, metals having a work function of 4.2 eV or less are preferably applied, and specific examples thereof include Li, Na, K, Be, Mg, Ca, Sr, Ba, Y, Cs, La, Sm, Gd, and Yb.

These electron-donating dopants may be used alone or in a combination of two or more of them.

An applied amount of the electron-donating dopants differs dependent on the types of the materials, but it is preferably 0.1% by mass to 99% by mass with respect to an electron transport layer material, more preferably 1.0% by mass to 80% by mass, and particularly preferably 2.0% by mass to 70% by mass. When the amount applied is less than 0.1% by mass, the efficiency of the present invention is insufficient so that it is not desirable, and when it exceeds 99% by mass, the electron transportation ability is deteriorated so that it is not preferred.

Specific examples of the materials applied for the electron injection layer and the electron transport layer include pyridine, pyrimidine, triazine, imidazole, triazole, oxazole, oxadiazole, fluorenone, anthraquinodimethane, anthrone, diphenylquinone, thiopyrandioxide, carbodiimide, imide, fluorenylidenemethane, distyrylpyradine, fluorine-substituted aromatic compounds, naphthalene, heterocyclic tetracarboxylic anhydrides such as perylene, phthalocyanine, and the derivatives thereof (which may form condensed rings with the other rings); and metal complexes represented by metal complexes of 8-quinolinol derivatives, metal phthalocyanine, and metal complexes containing benzoxazole, or benzothiazole as the ligand.

Although a thickness of the electron injection layer and the electron transport layer is not particularly limited, it is preferred that the thickness is in 1 nm to 5 μm, it is more preferably 5 nm to 1 μm, and it is particularly preferably 10 nm to 500 nm in view of decrease in driving voltage, improvements in luminescent efficiency, and improvements in durability.

The electron injection layer and the electron transport layer may have either a monolayered structure comprising one or two or more of the above-mentioned materials, or a multilayer structure composed of plural layers of a homogeneous composition or a heterogeneous composition.

When the carrier transportation layer adjacent to the light emitting layer is an electron transport layer, it is preferred that the Ea (ETL) of the electron transport layer is higher than the Ea (D) of the dopants contained in the light emitting layer in view of driving durability.

For the Ea (ETL), a value measured in accordance with the same manner as the measuring method of Ea, which will be mentioned later, is used.

Furthermore, the carrier mobility in the electron transport layer is usually from 10⁻⁷ cm².V⁻¹.s⁻¹ to 10⁻¹ cm².V⁻¹.s⁻¹, and in this range, from 10⁻⁵ cm².V⁻¹.s⁻¹ to 10⁻¹ cm².V⁻¹.s⁻¹ is preferable, from 10⁻⁴ cm².V⁻¹.s⁻¹ to 10⁻¹ cm².V⁻¹.s⁻¹ is more preferable, and from 10⁻³ cm².V⁻¹.s⁻¹ to 10⁻¹ cm².V⁻¹.s⁻¹ is particularly preferred, in view of luminescent efficiency.

Moreover, it is preferred that the carrier mobility in the electron transport layer is higher than that of the light emitting layer in view of driving durability. The carrier mobility is measured in accordance with the same method as that of the hole transport layer.

As to the carrier mobility of the luminescent device of the present invention, it is preferred that the carrier mobility in the hole transport layer, the electron transport layer, and the light emitting layer has the relationship of (electron transport layer≧hole transport layer)>light emitting layer in view of driving durability.

As the host material contained in the buffer layer, the below-mentioned hole transporting host or electron transporting host may be preferably used.

(Hole Blocking Layer)

A hole blocking layer is a layer having a function to prevent the holes transported from the anode to the light emitting layer from passing through to the cathode side. According to the present invention, a hole blocking layer may be provided as an organic compound layer adjacent to the light emitting layer on the cathode side.

The hole blocking layer is not particularly limited, but specifically, it may contain an aluminum complex such as BAlq, a triazole derivative, a pyrazabol derivative or the like.

It is preferred that a thickness of the hole blocking layer is generally 50 nm or less in order to lower the driving voltage, more preferably it is 1 nm to 50 nm, and further preferably it is 5 nm to 40 nm.

(Anode)

The anode may generally be any material as long as it has a function as an electrode for supplying holes to the organic compound layer, and there is no particular limitation as to the shape, the structure, the size or the like. However, it may be suitably selected from among well-known electrode materials according to the application and purpose of luminescent device. As mentioned above, the anode is usually provided as a transparent anode.

Materials for the anode may preferably include, for example, metals, alloys, metal oxides, electroconductive compounds, and mixtures thereof, and those having a work function of 4.0 eV or more are preferred. Specific examples of the anode materials include electroconductive metal oxides such as tin oxides doped with antimony, fluorine or the like (ATO and FTO), tin oxide, zinc oxide, indium oxide, indium tin oxide (ITO), and indium zinc oxide (IZO); metals such as gold, silver, chromium, and nickel; mixtures or laminates of these metals and the electroconductive metal oxides; inorganic electroconductive materials such as copper iodide and copper sulfide; organic electroconductive materials such as polyaniline, polythiophene, and polypyrrole; and laminates of these inorganic or organic electron-conductive materials with ITO. Among these, the electroconductive metal oxides are preferred, and particularly, ITO is preferable in view of productivity, high electroconductivity, transparency and the like.

The anode may be formed on the substrate in accordance with a method which is appropriately selected from among wet methods such as printing methods, coating methods and the like; physical methods such as vacuum deposition methods, sputtering methods, ion plating methods and the like; and chemical methods such as CVD and plasma CVD methods and the like, in consideration of the suitability to a material constituting the anode. For instance, when ITO is selected as a material for the anode, the anode may be formed in accordance with a DC or high-frequency sputtering method, a vacuum deposition method, an ion plating method or the like.

In the organic electroluminescence device of the present invention, a position at which the anode is to be formed is not particularly limited, but it may be suitably selected according to the application and purpose of the luminescent device. The anode may be formed on either the whole surface or a part of the surface on either side of the substrate.

For patterning to form the anode, a chemical etching method such as photolithography, a physical etching method such as etching by laser, a method of vacuum deposition or sputtering through superposing masks, or a lift-off method or a printing method may be applied.

A thickness of the anode may be suitably selected according to the material constituting the anode and is therefore not definitely decided, but it is usually in the range of around 10 nm to 50 μm, and preferably 50 nm to 20 μm.

A value of resistance of the anode is preferably 10³ Ω/□ or less, and 10² Ω/□ or less is more preferable. In the case where the anode is transparent, it may be either transparent and colorless, or transparent and colored. For extracting luminescence from the transparent anode side, it is preferred that a light transmittance of the anode is 60% or higher, and more preferably 70% or higher.

Concerning transparent anodes, there is a detailed description in “TOUMEI DENNKYOKU-MAKU NO SHINTENKAI (Novel Developments in Transparent Electrode Films)” edited by Yutaka Sawada, published by C.M.C. in 1999, the contents of which are incorporated by reference herein. In the case where a plastic substrate having a low heat resistance is applied, it is preferred that ITO or IZO is used to obtain a transparent anode prepared by forming the film at a low temperature of 150° C. or lower.

(Cathode)

The cathode may generally be any material as long as it has a function as an electrode for injecting electrons to the organic compound layer, and there is no particular limitation as to the shape, the structure, the size or the like. However it may be suitably selected from among well-known electrode materials according to the application and purpose of the luminescent device.

Materials constituting the cathode may include, for example, metals, alloys, metal oxides, electroconductive compounds, and mixtures thereof, and materials having a work function of 4.5 eV or less are preferred. Specific examples thereof include alkali metals (e.g., Li, Na, K, Cs or the like), alkaline earth metals (e.g., Mg, Ca or the like), gold, silver, lead, aluminum, sodium-potassium alloys, lithium-aluminum alloys, magnesium-silver alloys, rare earth metals such as indium, and ytterbium, and the like. They may be used alone, but it is preferred that two or more of them are used in combination from the viewpoint of satisfying both stability and electron injectability.

Among these, as the materials for constituting the cathode, alkaline metals or alkaline earth metals are preferred in view of electron injectability, and materials containing aluminum as a major component are preferred in view of excellent preservation stability.

The term “material containing aluminum as a major component” refers to a material constituted by aluminum alone; alloys comprising aluminum and 0.01% by mass to 10% by mass of an alkaline metal or an alkaline earth metal; or the mixtures thereof (e.g., lithium-aluminum alloys, magnesium-aluminum alloys and the like).

Regarding materials for the cathode, they are described in detail in JP-A Nos. 2-15595 and 5-121172, of which are incorporated by reference herein.

A method for forming the cathode is not particularly limited, but it may be formed in accordance with a well-known method.

For instance, the cathode may be formed in accordance with a method which is appropriately selected from among wet methods such as printing methods, coating methods and the like; physical methods such as vacuum deposition methods, sputtering methods, ion plating methods and the like; and chemical methods such as CVD and plasma CVD methods and the like, in consideration of the suitability to a material constituting the cathode. For example, when a metal (or metals) is (are) selected as a material (or materials) for the cathode, one or two or more of them may be applied at the same time or sequentially in accordance with a sputtering method or the like.

For patterning to form the cathode, a chemical etching method such as photolithography, a physical etching method such as etching by laser, a method of vacuum deposition or sputtering through superposing masks, or a lift-off method or a printing method may be applied.

In the present invention, a position at which the cathode is to be formed is not particularly limited, and it may be formed on either the whole or a part of the organic compound layer.

Furthermore, a dielectric material layer made of fluorides, oxides or the like of an alkaline metal or an alkaline earth metal may be inserted in between the cathode and the organic compound layer with a thickness of 0.1 nm to 5 nm. The dielectric layer may be considered to be a kind of electron injection layer. The dielectric material layer may be formed in accordance with, for example, a vacuum deposition method, a sputtering method, an ion-plating method or the like.

A thickness of the cathode may be suitably selected according to materials for constituting the cathode and is therefore not definitely decided, but it is usually in the range of around 10 nm to 5 μm, and preferably 50 nm to 1 μm.

Moreover, the cathode may be transparent or opaque. The transparent cathode may be formed by preparing a material for the cathode with a small thickness of 1 nm to 10 nm, and further laminating a transparent electroconductive material such as ITO or IZO thereon.

(Substrate)

According to the present invention, a substrate may be applied. The substrate to be applied is preferably one which does not scatter or attenuate light emitted from the organic compound layer. Specific examples of materials for the substrate include zirconia-stabilized yttrium (YSZ); inorganic materials such as glass; polyesters such as polyethylene terephthalate, polybutylene phthalate, and polyethylene naphthalate; and organic materials such as polystyrene, polycarbonate, polyethersulfon, polyarylate, polyimide, polycycloolefin, norbornene resin, poly(chlorotrifluoroethylene), and the like.

For instance, when glass is used as the substrate, non-alkali glass is preferably used with respect to the quality of material in order to decrease ions eluted from the glass. In the case of employing soda-lime glass, it is preferred to use glass on which a barrier coat such as silica has been applied. In the case of employing an organic material, it is preferred to use a material excellent in heat resistance, dimension stability, solvent resistance, electrical insulation, and workability.

There is no particular limitation as to the shape, the structure, the size or the like of the substrate, but it may be suitably selected according to the application, purposes and the like of the luminescent device. In general, a plate-like substrate is preferred as the shape of the substrate. A structure of the substrate may be a monolayer structure or a laminated structure. Furthermore, the substrate may be formed from a single member or two or more members.

Although the substrate may be in a transparent and colorless, or a transparent and colored condition, it is preferred that the substrate is transparent and colorless from the viewpoint that the substrate does not scatter or attenuate light emitted from the organic light emitting layer.

A moisture permeation preventive layer (gas barrier layer) may be provided on the front surface or the back surface of the substrate.

For a material of the moisture permeation preventive layer (gas barrier layer), inorganic substances such as silicon nitride and silicon oxide may be preferably applied. The moisture permeation preventive layer (gas barrier layer) may be formed in accordance with, for example, a high-frequency sputtering method or the like.

In the case of applying a thermoplastic substrate, a hard-coat layer or an under-coat layer may be further provided as needed.

(Protective Layer)

According to the present invention, the whole organic EL device may be protected by a protective layer.

A material contained in the protective layer may be one having a function to prevent penetration of substances such as moisture and oxygen, which accelerate deterioration of the device, into the device.

Specific examples thereof include metals such as In, Sn, Pb, Au, Cu, Ag, Al, Ti, Ni and the like; metal oxides such as MgO, SiO, SiO₂, Al₂O₃, GeO, NiO, CaO, BaO, Fe₂O₃, Y₂O₃, TiO₂ and the like; metal nitrides such as SiNₓ, SiNₓO_{y} and the like; metal fluorides such as MgF₂, LiF, AlF₃, CaF₂ and the like; polyethylene; polypropylene; polymethyl methacrylate; polyimide; polyurea; polytetrafluoroethylene; polychlorotrifluoroethylene; polydichlorodifluoroethylene; a copolymer of chlorotrifluoroethylene and dichlorodifluoroethylene; copolymers obtained by copolymerizing a monomer mixture containing tetrafluoroethylene and at least one comonomer; fluorine-containing copolymers each having a cyclic structure in the copolymerization main chain; water-absorbing materials each having a coefficient of water absorption of 1% or more; moisture permeation preventive substances each having a coefficient of water absorption of 0.1% or less; and the like.

There is no particular limitation as to a method for forming the protective layer. For instance, a vacuum deposition method, a sputtering method, a reactive sputtering method, an MBE (molecular beam epitaxial) method, a cluster ion beam method, an ion plating method, a plasma polymerization method (high-frequency excitation ion plating method), a plasma CVD method, a laser CVD method, a thermal CVD method, a gas source CVD method, a coating method, a printing method, or a transfer method may be applied.

(Sealing)

The whole organic electroluminescence device of the present invention may be sealed with a sealing cap.

Furthermore, a moisture absorbent or an inert liquid may be used to seal a space defined between the sealing cap and the luminescent device. Although the moisture absorbent is not particularly limited. Specific examples thereof include barium oxide, sodium oxide, potassium oxide, calcium oxide, sodium sulfate, calcium sulfate, magnesium sulfate, phosphorus pentoxide, calcium chloride, magnesium chloride, copper chloride, cesium fluoride, niobium fluoride, calcium bromide, vanadium bromide, molecular sieve, zeolite, magnesium oxide and the like. Although the inert liquid is not particularly limited, specific examples thereof include paraffins; liquid paraffins; fluorine-based solvents such as perfluoroalkanes, perfluoroamines, perfluoroethers and the like; chlorine-based solvents; silicone oils; and the like.

In the organic electroluminescence device of the present invention, when a DC (AC components may be contained as needed) voltage (usually 2 volts to 15 volts) or DC is applied across the anode and the cathode, luminescence can be obtained.

The driving durability of the organic electroluminescence device according to the present invention can be determined based on the brightness halftime at a specified brightness. For instance, the brightness halftime may be determined by using a source measure unit, model 2400, manufactured by KEITHLEY to apply a DC voltage to the organic EL device to cause it to emit light, conducting a continuous driving test under the condition that the initial brightness is 1500 cd/m² for green light emission, or 360 cd/m² for blue light emission, defining the time required for the brightness to reach 80% to the initial brightness as the brightness decaying time, and then comparing the resulting brightness decaying time with that of a conventional luminescent device. According to the present invention, the numerical value thus obtained was used.

An important characteristic parameter of the organic electroluminescence device of the present invention is external quantum efficiency. The external quantum efficiency is calculated by “the external quantum efficiency (φ)=the number of photons emitted from the device/the number of electrons injected to the device”, and it may be said that the larger the value obtained is, the more advantageous the device is in view of electric power consumption.

Moreover, the external quantum efficiency of the organic electroluminescence device is decided by “the external quantum efficiency (φ)=the internal quantum efficiency×light-extraction efficiency”. In an organic EL device which utilizes the fluorescent luminescence from the organic compound, an upper limit of the internal quantum efficiency is 25%, while the light-extraction efficiency is about 20%, and accordingly, it is considered that an upper limit of the external quantum efficiency is about 5%.

As the numerical value of the external quantum efficiency, the maximum value thereof when the device is driven at 20° C., or a value of the external quantum efficiency at about 100 cd/m² to 2000 cd/m² (preferably 1500 cd/m² in the case of green light emission, and 360 cd/m² in the case of blue light emission), when the device is driven at 20° C. may be used.

According to the present invention, a value obtained by the following method is used. Namely, a DC constant voltage is applied to the EL device by the use of a source measure unit, model 2400, manufactured by KEITHLEY to cause it to emit light, the brightness of the light is measured by using a brightness photometer (trade name: SR-3, manufactured by Topcon Corporation), and then, the external quantum efficiency at the luminescent brightness is calculated.

Further, an external quantum efficiency of the luminescent device may be obtained by measuring the luminescent brightness, the luminescent spectrum, and the current density, and calculating the external quantum efficiency from these results and a specific visibility curve. In other words, using the current density value, the number of electrons injected can be calculated. By an integration calculation using the luminescent spectrum and the specific visibility curve (spectrum), the luminescent brightness can be converted into the number of photons emitted. From the result, the external quantum efficiency (%) can be calculated by “(the number of photons emitted/the number of electrons injected to the device)×100”.

For the driving method of the organic electroluminescence device of the present invention, driving methods described in JP-A Nos. 2-148687, 6-301355, 5-29080, 7-134558, 8-234685, and 8-241047; Japanese Patent No. 2784615, U.S. Pat. Nos. 5,828,429 and 6,023,308 are applicable.

### 3. Inorganic Electroluminescence Device

An inorganic electroluminescence device includes first and second insulative films disposed between electrodes and comprising an oxide having a high dielectric constant, and a functional layer such as a light emitting layer comprising a sulfide interposed between the insulative films. As the insulative layer, materials such as tantalum pentoxide (Ta₂O₅), titanium oxide (TiO₂), yttrium oxide (Y₂O₃), barium titanate (BaTiO₃), and strontium titanate (SrTiO₃) can be used. As the light emitting layer, those using materials such as zinc sulfide (ZnS), calcium sulfide (CaS), strontium sulfide (SrS) or barium thioaluminate (BaAl₂S₄) as a host material of the light emitting layer and containing a micro-amount of transition metal elements such as manganese (Mn) and rare earth elements such as europium (Eu) cerium (Ce) or terbium (Tb), as a light emission center can be used.

### 4. Application

The application of the light emitting device in the present invention is not particularly restricted, but can be appropriately used for displays for portable phone, personal digital assistants (PDA), computer displays, car communication displays, TV monitors, or conventional illumination light sources and the like.

### EXAMPLES

In the following, examples of the organic electroluminescence device of the present invention will be described, but it should be noted that the present invention is not limited to these examples.

### Example 1

### 1. Preparation of the Organic EL Device

(Preparation of Comparative Organic EL Device No. A1)

A 2.5 cm square ITO glass substrate having a 0.5 mm thickness (manufactured by Geomatec Co., Ltd.; surface resistance: 10 Ω/□) was placed in a washing container to apply ultrasonic cleaning in 2-propanol, and then, UV-ozone treatment was applied for 30 minutes. On the transparent anode, the following layers were deposited in accordance with a vacuum deposition method. In the examples of the present invention, a deposition rate was 0.2 nm/second, unless otherwise specified, wherein the deposition rate was measured by the use of a quartz oscillator. The thicknesses of layers described below were also measured by using the quartz oscillator.

—Hole Injection Layer—

On the ITO layer, CuPc was deposited by evaporation method at a thickness of 10 nm.

—Hole Transport Layer—

On the hole injection layer, α-NPD was deposited by evaporation method at a thicknessof 10 nm.

—Light Emitting Layer—

CBP and Ir(ppy)₃ were co-deposited at a volume ratio of 95:5. The thickness of the light emitting layer was 60 nm.

—Electron Transport Layer—

BAlq was deposited by evaporation method at a thickness of 10 nm.

—Electron Injection Layer—

Alq was deposited by evaporation method at a thickness of 20 nm.

On the resulting layers, a patterned mask (mask by which the light emitting region becomes 2 mm×2 mm) was disposed, and lithium fluoride was deposited at a thickness of 1 nm at a deposition rate of 0.01 nm/second to obtain an electron injection layer. Further, metal aluminum was deposited thereon with a 100 nm thickness to obtain a cathode.

The prepared lamination body was placed in a globe box whose the contents were replaced by argon gas, and it was sealed by the use of a sealing cap made of stainless steel and a UV curable adhesive (trade name: XNR5516HV, manufactured by Nagase-Ciba Co., Ltd.).

Thus, the comparative organic EL device No. A1 was obtained.

### (Manufacture of Organic EL device No. 1 of the Invention)

In the Comparative organic EL device No. A1, the light emitting layer is divided into two sub units as shown below, and the following intermediate layer A was disposed as the following conductive charge blocking layer between each of the divided light emitting layers.

Light emitting layer 1: A light emitting layer of a composition identical with that of Comparative device No. A1 was vapor deposited to a thickness of 20 nm.

Intermediate layer A: Compound A, CBP, and Ir(ppy)₃ were co-vapor deposited such that the volume ratio was 55:40:5. The thickness of the intermediate layer was set to 20 nm.

Light emitting layer 2: A light emitting layer of a composition identical with that of Comparative device No. A1 was vapor deposited to a thickness of 20 nm.

### 2. Result of Performance Evaluation

For the obtained comparative organic EL device No. A1 and the organic EL device No. 1 of the invention, the external quantum efficiency was measured under the same conditions and by the following means.

### (Measuring Method for External Quantum Efficiency)

For the prepared light emitting device, a DC voltage was applied by using a source measure unit model 2400 manufactured by KEITHLEY Instruments Inc. to the light emitting device thereby emit light. The emission spectrum and the amount of light were measured by using a brightness meter SR-3 manufactured by Topcon Corp., and the external quantum efficiency was calculated based on the emission spectrum, the amount of light, and the current during measurement.

As a result, while the external quantum efficiency was 5.62% in the comparative organic El device No. A1, the external quantum efficiency was 8.23% in the organic EL device No. 1 of the invention. It was quite unexpected result that a high external quantum efficiency was shown although the total thickness for the intermediate layer and the two light emitting layers was equal with the 60 nm thickness for the comparative organic EL device.

### Example 2

### 1. Manufacture of Organic EL Device

(Manufacture of Comparative Organic EL device No. A2)

A comparative organic EL device No. A2 was manufactured in the same manner as in the comparative organic EL device No. A1 except for changing the vapor deposition thickness for the light emitting layer to 110 nm in the manufacture of the comparative organic EL device No. A1.

### (Manufacture of Organic EL Device No. 2 of the Invention)

In the comparative organic EL device No. A2, the light emitting layer was divided into 6 layers of unit light emitting layer and the following intermediate layer B is disposed between each of the unit light emitting layers.

Unit light emitting layers 1-6: Vapor deposited with a composition identical with the light emitting layer of comparative organic EL device No. A1 to a thickness of 10 nm.

Intermediate layer B: Compound B, CBP, and Ir(ppy)₃ were co-vapor deposited such that the volume ratio was 47.5:47.5:5. The thickness of the intermediate layer B was set to 10 nm.

That is, it has a constitution finely divided into 11 layers in total for unit light emitting device 1/intermediate layer B/unit light emitting layer 2/intermediate layer B/unit light emitting layer 3/intermediate layer B/unit light emitting layer 4/intermediate layer B/unit light emitting layer 5/intermediate layer B/unit light emitting layer 6, having a total thickness of 110 nm, which is identical with the light emitting layer of the comparative organic EL device No. A2.

### 2. Result of Performance Evaluation

For the obtained comparative organic EL device No. A2 and the organic EL device No. 2 of the invention, the external quantum efficiency was measured in the same manner as in Example 1.

As a result while the external quantum efficiency of comparative organic EL device No. A2 was 6.81%, the external quantum efficiency of the organic EL device No. 2 of the invention showed an extremely high value of 8.77%.

### Example 3

### 1. Manufacture of Organic EL Device

(Manufacture of Comparative Organic EL Device No. A3)

A comparative organic EL device No. A3 was manufactured in the same manner as in the comparative organic EL device No.A1 except for changing the hole injection layer, the hole transport layer, the light emitting layer, the electron transport layer, and the electron injection layer to the following composition in the manufacture of the comparative organic EL device No. A1.

Hole injection layer: 2-TNATA and F4-TCNQ (tetrafluoro tetracyano quinodimethane) were co-vapor deposited such that F4-TCNQ was 0.3 mass % relative to 2-TNATA on the same ITO substrate as in Example 1. The thickness was 160 nm.

Hole transport layer: α-NPD was vapor deposited to a thickness of 10 nm on the hole injection layer.

Light emitting layer: mCP and FIrpic were co-vapor deposited such that the volume ratio is from 90 to 10. The thickness of the light emitting layer was set to 120 nm.

Electron transport layer: BAlq was vapor deposited to a thickness of 10 nm on the light emitting layer.

Electron injection layer: Alq was vapor deposited to a thickness of 20 nm on the electron transport layer.

### (Manufacture of Organic EL device No. 3 of the Invention)

In the comparative organic EL device No. A3, the light emitting layer was divided into the following four layers of unit light emitting layer and the following intermediate layer C is disposed between each of the unit light emitting layers.

Unit light emitting layer 11-14: Vapor deposited with a composition identical with the light emitting layer of comparative organic EL device No. A3 to 15 nm thickness.

Intermediate layer C: Compound A, mCP, and FIrpic were co-vapor deposited such that the volume ratio was 70:10:20. The thickness of the intermediate layer C was set to 20 nm.

That is, it has a constitution finely divided into 7 layers in total for unit light emitting device 11/intermediate layer C/unit light emitting layer 12/intermediate layer C/unit light emitting layer 13/intermediate layer C/unit light emitting layer 14, having a total thickness of 120 nm, which is identical with the light emitting layer of the comparative organic EL device No. A3.

### 2. Result of Performance Evaluation

For the obtained comparative organic EL device No. A3 and the organic EL device No. 3 of the invention, the external quantum efficiency was measured in the same manner as in Example 1.

As a result, while the external quantum efficiency of comparative organic EL device No. A3 was 2.47%, the external quantum efficiency of the organic EL device No. 3 of the invention was improved as 5.22%.

### Example 4

### 1. Manufacture of Organic EL Device

(Manufacture of Comparative Organic EL Device No. A4)

A comparative organic EL device No. A4 was manufactured in the same manner as in the comparative organic EL device No. A3 except for changing the light emitting materials to Ir(ppy)₃, and the thickness of the light emitting layer to 110 nm.

### (Manufacture of Organic EL Device No. 4 of the Invention)

In the comparative organic EL device No. A4, the light emitting layer was divided into the following six layers of unit light emitting layer and the following intermediate layer D is disposed between each of the unit light emitting layers.

Unit light emitting layer 21-26: Vapor deposited with a composition identical with the light emitting layer of comparative organic EL device No. A4 to a thickness of 10 nm.

Intermediate layer D: Compound B, mCP, and Ir(ppy)₃ were co-vapor deposited such that the volume ratio was 45:45:10. The thickness of the intermediate layer D was set to 10 nm.

That is, it has a constitution finely divided into 11 layers in total for unit light emitting layer 21/intermediate layer D/ unit light emitting layer 22/intermediate layer D/unit light emitting layer 23/intermediate layer D/unit light emitting layer 24/intermediate layer D/unit light emitting layer 25/intermediate layer D/unit light emitting layer 26, having a total thickness of 110 nm, which is identical with the light emitting layer of the comparative organic EL device No. A4.

### 2. Result of Performance Evaluation

For the obtained comparative organic EL device No. A4 and the organic EL device No. 4 of the invention, the external quantum efficiency was measured in the same manner as in Example 1.

As a result, while the external quantum efficiency of comparative organic EL device No. A4 was 5.67%, the external quantum efficiency of the organic EL device No. 4 of the invention was improved as 8.92%.

### Example 5

### 1. Manufacture of Organic EL Device

(Manufacture of Comparative Organic EL Device No. A5)

A comparative organic EL device No. A5 was manufactured in the same manner as in the comparative organic EL device No. A1 except for changing the hole injection layer, the hole transport layer, the electron injection layer and the electron transport layer to those, respectively, identical that are used in Example 3.

### (Manufacture of Organic EL Device No. 5 of the Invention)

In the comparative organic EL device No. A5, the light emitting layer was divided into the following two layers of unit light emitting layer and the following intermediate layer E is disposed between the unit light emitting layers.

Unit light emitting layer 31, 32: Vapor deposited with a composition identical with the light emitting layer of comparative organic EL device No. A5 to a thickness of 25 nm.

Intermediate layer E: Compound A, CBP, and Ir(ppy)₃ were co-vapor deposited such that the volume ratio was 80:10:10. The thickness of the intermediate layer E was set to 10 nm.

### 2. Result of Performance Evaluation

For the obtained comparative organic EL device No. A5 and the organic EL device No. 5 of the invention, the external quantum efficiency was measured in the same manner as in Example 1.

As a result, while the external quantum efficiency of comparative organic EL device No. A5 was 6.27%, the external quantum efficiency of the organic EL device No. 5 of the invention was improved as 8.99%.

### Example 6

### 1. Manufacture of Organic EL Device

(Manufacture of Comparative Organic EL Device No. A6)

A comparative organic EL device No. A6 was manufactured in the same manner as in the comparative organic EL device No. A1 except for changing the thickness of the light emitting layer to 100 nm.

### (Manufacture of Organic EL Device No. 6 of the Invention)

### No. 6 of the invention was extremely high as 9.02%.

### Example 7

### 1. Manufacture of Organic EL Device

### (Manufacture of Organic EL Device No. 7 of the Invention)

In the comparative organic EL device No. A6, the light emitting layer was divided into the following three layers of unit light emitting layer and the following intermediate layer B was disposed between each of the unit light emitting layers, and a hole blocking layer was disposed between the light emitting layer and the electron transport layer.

Unit light emitting layer 11˜13: Vapor deposited with a composition identical with the light emitting layer of comparative organic EL device No. A1 to a thickness of 20 nm.

Intermediate layer B: Compound B, CBP, and Ir(ppy)₃ were co-vapor deposited such that the volume ratio was 47.5:47.5:5. The thickness of the intermediate layer B was set to 20 nm.

Hole blocking layer: Compound D and Ir(ppy)₃ were co-vapor deposited such that the volume ratio was 95:5. The thickness of the hole blocking layer was set to 10 nm.

That is, an organic EL device was prepared, having a constitution of anode/hole injection layer/hole transport layer/unit light emitting layer 1/intermediate layer B/unit light emitting layer 2/intermediate layer B/unit light emitting layer 3/hole blocking layer/electron transport layer/electron injection layer/cathode.

### 2. Result of Performance Evaluation

For the obtained organic EL device No. 7 of the invention, the external quantum efficiency was measured in the same manner as in Example 1.

As a result, while the external quantum efficiency of comparative organic EL device No. A6 was 6.41%, the external quantum efficiency of the organic EL device No. 7 of the invention was extremely high as 9.11%.

### Example 8

### 1. Manufacture of Organic EL Device

### (Manufacture of Organic EL Device No. 8 of the Invention)

In the comparative organic EL device No. A6, the light emitting layer was divided into the following three layers of unit light emitting layer and the following intermediate layer B was disposed between each of the unit light emitting layers, an electron blocking layer was disposed between the light emitting layer and the hole transport layer, and a hole blocking layer was disposed between the light emitting layer and the electron transport layer.

Unit light emitting layer 11˜13: Vapor deposited with a composition identical with the light emitting layer of comparative organic EL device No. A1 to a thickness of 20 nm.

Intermediate layer B: Compound B, CBP, and Ir(ppy)₃ were co-vapor deposited such that the volume ratio was 47.5:47.5:5. The thickness of the intermediate layer B was set to 20 nm.

Electron blocking layer: Compound C and Ir(ppy)₃ were co-vapor deposited such that the volume ratio was 95:5. The thickness of the electron blocking layer was set to 10 nm.

Hole blocking layer: Compound D and Ir(ppy)₃ were co-vapor deposited such that the volume ratio was 95:5. The thickness of the hole blocking layer was set to 10 nm.

That is, an organic EL device was prepared, having a constitution of anode/hole injection layer/hole transport layer/electron blocking layer/unit light emitting layer 1/intermediate layer B/unit light emitting layer 2/intermediate layer B/unit light emitting layer 3/hole blocking layer/electron transport layer/electron injection layer/cathode.

### 2. Result of Performance Evaluation

For the obtained organic EL device No. 8 of the invention, the external quantum efficiency was measured in the same manner as in Example 1.

As a result, while the external quantum efficiency of comparative organic EL device No. A6 was 6.41%, the external quantum efficiency of the organic EL device No. 8 of the invention was extremely high as 9.80%.

Structures of the compounds used in the above-described luminescent devices are shown below.

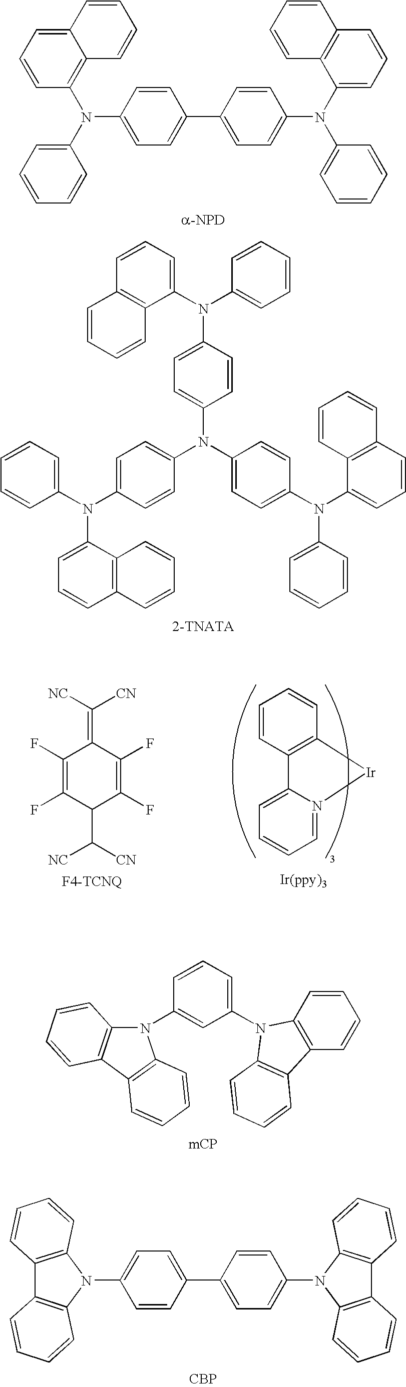

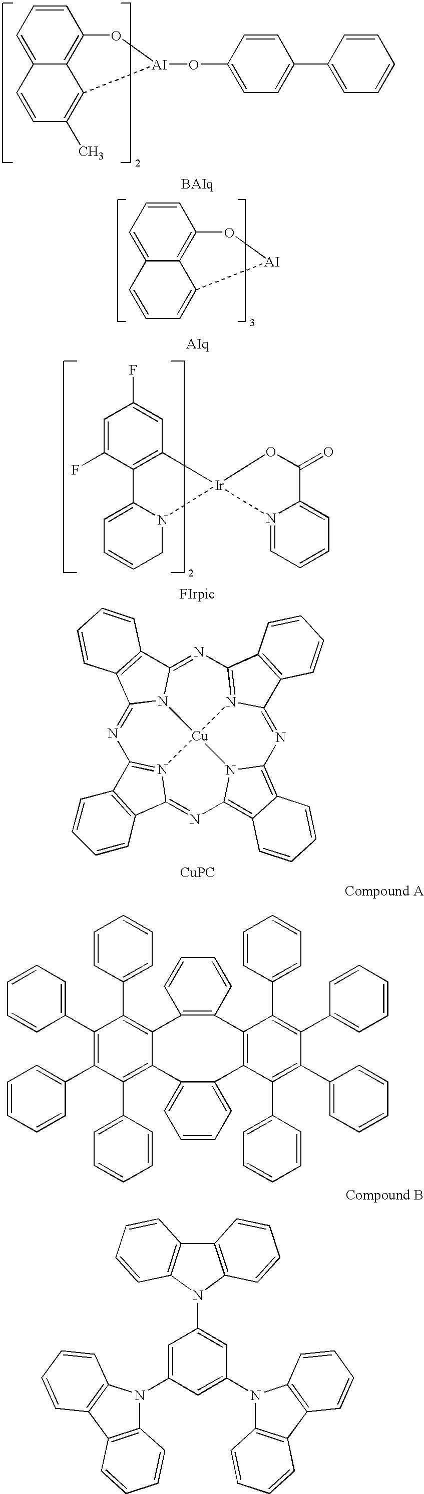

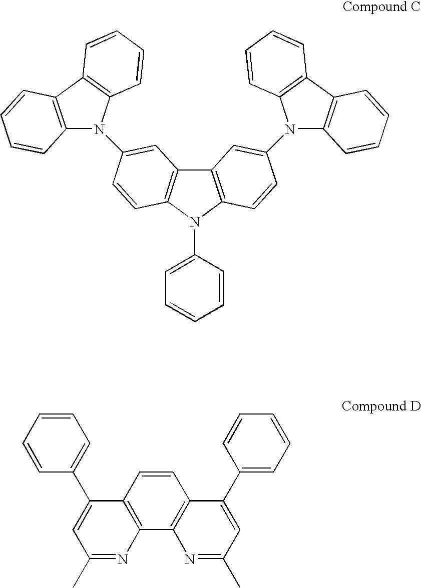

In the comparative organic EL device No. A6, the light emitting layer was divided into the following three layers of unit light emitting layer and the following intermediate layer B was disposed between each of the unit light emitting layers, and an electron blocking layer was disposed between the light emitting layer and the hole transport layer.

Unit light emitting layer 11˜13: Vapor deposited with a composition identical with the light emitting layer of comparative organic EL device No. A1 to a thickness of 20 nm.

Intermediate layer B: Compound B, CBP, and Ir(ppy)₃ were co-vapor deposited such that the volume ratio was 47.5:47.5:5. The thickness of the intermediate layer B was set to 20 nm.

Electron blocking layer: Compound C and Ir(ppy)₃ were co-vapor deposited such that the volume ratio was 95:5. The thickness of the electron blocking layer was set to 10 nm.

That is, an organic EL device was prepared, having a constitution of anode/hole injection layer/hole transport layer/electron blocking layer/unit light emitting layer 11/intermediate layer B/unit light emitting layer 12/intermediate layer B/unit light emitting layer 13/electron transport layer/electron injection layer/cathode.

### 2. Result of Performance Evaluation

For the obtained comparative organic EL device No. A6 and the organic EL device No. 6 of the invention, the external quantum efficiency was measured in the same manner as in Example 1.

As a result, while the external quantum efficiency of comparative organic EL device No. A6 was 6.41%, the external quantum efficiency of the organic EL device

What is claimed is:

1. A light emitting device having at least a light emitting layer between a pair of electrodes, wherein the light emitting layer is divided into plural layers in the thickness direction thereof, and an intermediate layer containing at least one of a charge transport material or a light emitting material is positioned between each of the divided layers of the light emitting layer.

2. A light emitting device according to claim 1, wherein the light emitting layer is divided into 2 to 50 layers in the thickness direction thereof, and the thickness of each divided layer of the light emitting layer is 2 to 50 nm.

3. A light emitting device according to claim 1, wherein the intermediate layer is a conductive charge blocking layer.

4. A light emitting device according to claim 1, wherein the intermediate layer contains the charge transport material and the light emitting material.

5. A light emitting device according to claim 4, wherein the charge transport material is a hole transport material or an electron transport material.

6. A light emitting device according to claim 1, wherein the light emitting device further comprises an electron blocking layer between an anode and a divided light emitting layer nearest to the anode and adjacent to the divided light emitting layer nearest to the anode.

7. A light emitting device according to claim 6, wherein the electron blocking layer contains a light emitting material.

8. A light emitting device according to claim 1, wherein the light emitting device further comprises a hole blocking layer between a cathode and a divided light emitting layer nearest to the cathode and adjacent to the divided light emitting layer nearest to the cathode.

9. A light emitting device according to claim 8, wherein the hole blocking layer contains a light emitting material.

10. A light emitting device according to claim 1, wherein a light emitting material of the light emitting layer contains a phosphorescence material.

11. A light emitting device according to claim 1, wherein the light emitting material in the intermediate layer contains a phosphorescence material.

12. A light emitting device according to claim 1, wherein the light emitting device is an organic electroluminescence device.
